(19) United States
(12) Patent Application Publication
(10) Pub. No.: US 2023/0261029 A1
(43) Pub. Date: Aug. 17, 2023

(54) LIGHT-RECEIVING ELEMENT AND MANUFACTURING METHOD THEREOF, AND ELECTRONIC DEVICE

(71) Applicant: SONY SEMICONDUCTOR SOLUTIONS CORPORATION, Kanagawa (JP)

(72) Inventor: Yoshiki EBIKO, Kanagawa (JP)

(73) Assignee: SONY SEMICONDUCTOR SOLUTIONS CORPORATION, Kanagawa (JP)

(21) Appl. No.: 18/004,778

(22) PCT Filed: Jul. 2, 2021
(86) PCT No.: PCT/JP2021/025084

§ 371 Date: Jan. 9, 2023

(30) Foreign Application Priority Data
Jul. 17, 2020 (JP) 2020-122781

(51) Int. Cl. H01L 27/146

(52) U.S. Cl. CPC H01L 27/14652; H01L 27/14647; H01L 27/14636; H01L 27/14612; H01L 27/14689

(57) ABSTRACT

The present technique relates to a light-receiving element that enables a dark current to be suppressed while improving quantum efficiency using Ge or SiGe, a method of manufacturing the light-receiving element, and an electronic device. The light-receiving element includes: a pixel array region where pixels in which at least a photoelectric conversion region is formed of a SiGe region or a Ge region are arrayed in a matrix pattern; and an AD converting portion provided in pixel units of one or more pixels. The present technique can be applied to, for example, a ranging module that measures a distance to a subject, and the like.

### TECHNICAL FIELD

The present technique relates to a light-receiving element and a manufacturing method thereof, and an electronic device, and particularly, to a light-receiving element configured to be capable of suppressing a dark current while improving quantum efficiency using Ge or SiGe and a manufacturing method of the light-receiving element, and to an electronic device.

### BACKGROUND ART

Ranging modules using an indirect ToF (Time of Flight) system are known. In a ranging module adopting the indirect ToF system, irradiating light is emitted toward an object and reflected light that returns after being reflected by a surface of the object is received by a light-receiving element. The light-receiving element distributes a signal electric charge obtained by photoelectrically converting the reflected light to, for example, two electric charge storage regions, and a distance is calculated based on a distribution ratio of the signal electric charge. In such light-receiving elements, a light-receiving element with improved light-receiving characteristics due to adopting backside illumination is proposed (for example, refer to PTL 1).

Generally, light in a near-infrared region is used as irradiating light of a ranging module. When a silicon substrate is used as a semiconductor substrate of a light-receiving element, light in a near-infrared region has low quantum efficiency (QE) and causes a decline in sensor sensitivity.

### CITATION LIST

### Patent Literature

[PTL 1]
WO 2018/135320

### SUMMARY

### Technical Problem

Ge (germanium) or SiGe can conceivably be introduced as a semiconductor substrate in order to improve quantum efficiency of infrared light.

However, a substrate using Ge or SiGe as compared to Si (silicon) sustains an increase in dark current due to defects in bulk or defects in a Si/Ge layer.

The present technique has been devised in view of such circumstances and an object thereof is to enable a dark current to be suppressed while improving quantum efficiency using Ge or SiGe.

### Solution to Problem

A light-receiving element according to a first aspect of the present technique includes: a pixel array region where pixels in which at least a photoelectric conversion region is formed of an SiGe region or a Ge region are arrayed in a matrix pattern; and an AD converting portion provided in pixel units of one or more pixels.

A manufacturing method of a light-receiving element according to a second aspect of the present technique includes: forming, in a light-receiving element including a pixel array region where pixels are arrayed in a matrix pattern and an AD converting portion provided in pixel units of one or more pixels, at least a photoelectric conversion region of each pixel by a SiGe region or a Ge region.

An electronic device according to a third aspect of the present technique includes: a light-receiving element including: a pixel array region where pixels in which at least a photoelectric conversion region is formed of an SiGe region or a Ge region are arrayed in a matrix pattern; and an AD converting portion provided in pixel units of one or more pixels.

In the first to third aspects of the present technique, a light-receiving element is provided with a pixel array region where pixels are arrayed in a matrix pattern and an AD converting portion provided in pixel units of one or more pixels, and at least a photoelectric conversion region of each pixel is formed by a SiGe region or a Ge region.

The light-receiving element and the electronic device may be independent apparatuses or may be modules to be incorporated into other apparatuses.

### BRIEF DESCRIPTION OF DRAWINGS

FIG. 1 is a block diagram showing a schematic configuration example of a light-receiving element to which the present technique is applied.

FIG. 2 is a sectional view showing a first configuration example of pixels.

FIG. 3 is a diagram showing a circuit configuration of a pixel.

FIG. 4 is a plan view showing an arrangement example of a pixel circuit shown in FIG. 3.

FIG. 5 is a diagram showing another circuit configuration example of a pixel.

FIG. 6 is a plan view showing an arrangement example of a pixel circuit shown in FIG. 5.

FIG. 7 is a plan view showing an arrangement of pixels in a pixel array portion.

FIG. 8 is a diagram for explaining a first formation method of a SiGe region.

FIG. 9 is a diagram for explaining a second formation method of a SiGe region.

FIG. 10 is a plan view showing another example of formation of a SiGe region in a pixel.

FIG. 11 is a diagram for explaining a formation method of the pixel shown in FIG. 10.

FIG. 12 is a schematic perspective view showing a substrate configuration example of a light-receiving element.

FIG. 13 is a sectional view of a pixel when constituted by a laminated structure of two substrates.

FIG. 14 is a schematic sectional view of a light-receiving element formed by laminating three semiconductor substrates.

FIG. 15 is a plan view of a pixel when adopting a 4-tap pixel structure.

FIG. 16 is a diagram showing another example of formation of a SiGe region.

FIG. 17 is a diagram showing another example of formation of a SiGe region.

FIG. 18 is a sectional view showing an example of Ge concentration.

FIG. 19 is a block diagram showing a detailed configuration example of a pixel when each pixel includes an AD converting portion.

FIG. 20 is a circuit diagram showing detailed configurations of a comparator circuit and a pixel circuit.

FIG. 21 is a circuit diagram showing a connection between output of each tap of a pixel circuit and a comparator circuit.

FIG. 22 is a sectional view showing a second configuration example of pixels.

FIG. 23 is an enlarged sectional view of a vicinity of a pixel transistor shown in FIG. 22.

FIG. 24 is a sectional view showing a third configuration example of pixels.

FIG. 25 is a diagram showing a circuit configuration of a pixel in a case of an IR imaging sensor.

FIG. 26 is a sectional view of pixels in a case of an IR imaging sensor.

FIG. 27 is a diagram showing a pixel arrangement example in a case of an RGBIR imaging sensor.

FIG. 28 is a sectional view showing an example of a color filter layer in a case of an RGBIR imaging sensor.

FIG. 29 is a diagram showing a circuit configuration example of a SPAD pixel.

FIG. 30 is a diagram for explaining operations of the SPAD pixel shown in FIG. 29.

FIG. 31 is a sectional view showing a configuration example in a case of a SPAD pixel.

FIG. 32 is a diagram showing a circuit configuration example in a case of a CAPD pixel.

FIG. 33 is a sectional view showing a configuration example in a case of a CAPD pixel.

FIG. 34 is a block diagram showing a configuration example of a ranging module to which the present technique is applied.

FIG. 35 is a block diagram showing a configuration example of a smartphone as an electronic device to which the present technique is applied.

FIG. 36 is a block diagram showing an example of a schematic configuration of a vehicle control system.

FIG. 37 is an explanatory diagram showing an example of installation positions of an external vehicle information detecting portion and an imaging portion.

### DESCRIPTION OF EMBODIMENTS

Modes for embodying the present technique (hereinafter, referred to as embodiments) will be described below with reference to the accompanying drawings. In the present specification and the drawings, components having substantially a same functional configuration will be denoted by same reference signs and, accordingly, redundant descriptions thereof will be omitted. The description will be presented in the following order.

1. Configuration example of light-receiving element
2. Sectional view according to first configuration example of pixel
3. Circuit configuration example of pixel
4. Plan view of pixel
5. Another circuit configuration example of pixel
6. Plan view of pixel
7. Formation method of GeSi region
8. Modification of first configuration example
9. Substrate configuration example of light-receiving element
10. Sectional view of pixel in case of laminated structure
11. Laminated structure of three substrates
12. Configuration example of 4-tap pixel
13. Another example of formation of SiGe region
14. Detailed configuration example of pixel area ADC
15. Sectional view according to second configuration example of pixel
16. Sectional view according to third configuration example of pixel
17. Configuration example of IR imaging sensor
18. Configuration example of RGBIR imaging sensor
19. Configuration example of SPAD pixel
20. Configuration example of CAPD pixel
21. Configuration example of ranging module
22. Configuration example of electronic device
23. Example of application to mobile body

Note that, in drawings to be referred to in the following description, same or similar portions are denoted by same or similar reference signs. However, the drawings are schematic and relationships between thicknesses and plan view dimensions, ratios of thicknesses of respective layers, and the like differ from those in reality. In addition, the drawings may include portions where dimensional relationships and ratios differ among the drawings.

Furthermore, it is to be understood that definitions of directions such as upward and downward in the following description are merely definitions provided for the sake of brevity and are not intended to limit technical ideas of the present disclosure. For example, when an object is observed after being rotated by 90 degrees, up-down is converted into and interpreted as left-right, and when an object is observed after being rotated by 180 degrees, up-down is interpreted as being inverted.

### <1. Configuration Example of Light-Receiving Element>

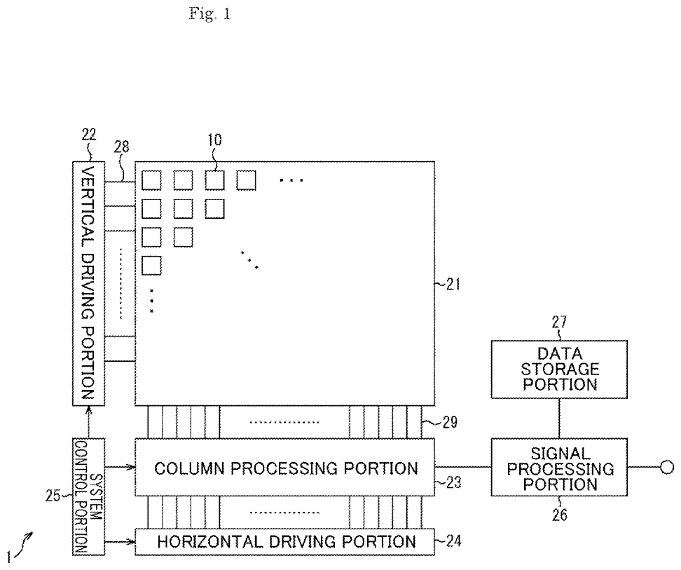

FIG. 1 is a block diagram showing a schematic configuration example of a light-receiving element to which the present technique is applied.

A light-receiving element 1 shown in FIG. 1 is a ranging sensor that outputs ranging information according to an indirect ToF system.

The light-receiving element 1 receives light (reflected light) being light (irradiating light) emitted from a predetermined light source and reflected by an object and outputs a depth image that stores information on a distance to the object as a depth value. Note that irradiating light emitted from the light source is infrared light with a wavelength of, for example, 780 nm or more and is pulse light that is repetitively turned on and off at predetermined periods.

The light-receiving element 1 includes a pixel array portion 21 formed on a semiconductor substrate (not illustrated) and a peripheral circuit portion. The peripheral circuit portion is constituted by, for example, a vertical driving portion 22, a column processing portion 23, a horizontal driving portion 24, and a system control portion 25.

The light-receiving element 1 is further provided with a signal processing portion 26 and a data storage portion 27. Note that the signal processing portion 26 and the data storage portion 27 may be mounted on the same substrate as that of the light-receiving element 1 or arranged on a substrate in a different module from that the light-receiving element 1.

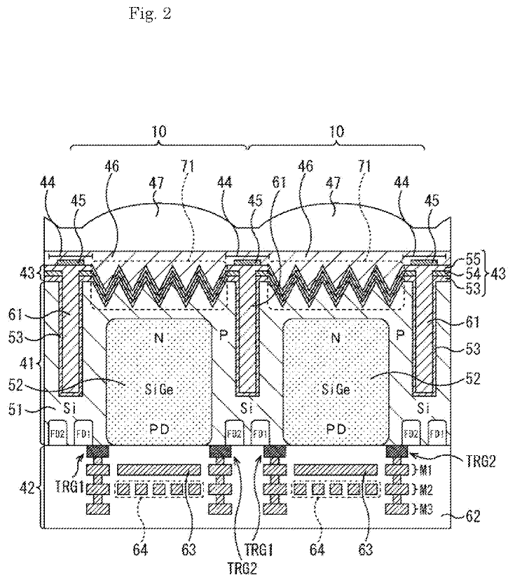

The pixel array portion 21 generates an electric charge corresponding to an amount of received light and is configured such that pixels 10 to output a signal corresponding to the electric charge are arrayed in a matrix pattern in a row direction and a column direction. In other words, the pixel array portion 21 includes a plurality of pixels 10 which photoelectrically convert incident light and which outputs a signal in accordance with an electric charge obtained as a result of the photoelectric conversion. Details of the pixel 10 will be described later in FIG. 2 and the subsequent drawings.

In this case, the row direction refers to an array direction of the pixels 10 in the horizontal direction and the column direction refers to an array direction of the pixels 10 in the vertical direction. The row direction is a transverse direction in the drawings and the column direction is a longitudinal direction in the drawings.

In the pixel array portion 21, with respect to the matrix-like pixel array, a pixel drive line 28 is wired in the row direction for each pixel row and two vertical signal lines 29 are wired in the column direction for each pixel column. For example, the pixel drive line 28 transmits a drive signal for driving at the time of reading of a signal from the pixel 10. Note that, while one wiring is shown for the pixel drive line 28 in FIG. 1, the number of wirings is not limited to one. One end of the pixel drive line 28 is connected to an output end corresponding to each row of the vertical driving portion 22.

The vertical driving portion 22 is constituted by a shift register, an address decoder, or the like and drives each of the pixels 10 of the pixel array portion 21 at the same time, in units of rows, or the like. In other words, along with the system control portion 25 that controls the vertical driving portion 22, the vertical driving portion 22 constitutes a control circuit that controls an operation of each pixel 10 of the pixel array portion 21.

A pixel signal which is output from each pixel 10 of a pixel row in accordance with drive control by the vertical driving portion 22 is input to the column processing portion 23 through the vertical signal line 29. The column processing portion 23 performs predetermined signal processing on a pixel signal which is output from each pixel 10 through the vertical signal line 29, and temporarily holds the pixel signal having been subjected to the signal processing. Specifically, the column processing portion 23 performs noise removal processing, AD (Analog to Digital) conversion processing, or the like as the signal processing.

The horizontal driving portion 24 is constituted by a shift register, an address decoder, or the like and sequentially selects a unit circuit corresponding to a pixel column of the column processing portion 23. Through selective scanning by the horizontal driving portion 24, pixel signals subjected to the signal processing for each unit circuit in the column processing portion 23 are sequentially output.

The system control portion 25 is constituted by a timing generator for generating various timing signals or the like and performs drive control of the vertical driving portion 22, the column processing portion 23, the horizontal driving portion 24, and the like based on the various timing signals generated by the timing generator.

The signal processing portion 26 has at least a calculation processing function and performs various signal processing such as calculation processing based on a pixel signal which is output from the column processing portion 23. When the signal processing portion 26 performs signal processing, the data storage portion 27 temporarily stores data required for the signal processing.

The light-receiving element 1 configured as described above has a circuit configuration called column ADC in which an AD conversion circuit that performs AD conversion processing is arranged for each pixel column in the column processing portion 23.

The light-receiving element 1 outputs a depth image in which information on a distance to an object is stored in a pixel value as a depth value. For example, the light-receiving element 1 is used in an in-vehicle system which is mounted to a vehicle and which measures a distance to a target outside of the vehicle, gesture recognition processing which measures a distance to a target such as a hand of a user and which recognizes a gesture by the user based on a result of the measurement, and the like.

### <2. Sectional View According to First Configuration Example of Pixel>

FIG. 2 is a sectional view showing a first configuration example of the pixels 10 arranged in the pixel array portion 21.

The light-receiving element 1 includes a semiconductor substrate 41 and a multilayer wiring layer 42 formed on a front surface side (a lower side in the drawing) of the semiconductor substrate 41.

The semiconductor substrate 41 is constituted of, for example, silicon (hereinafter, referred to as Si) and is formed so as to have a thickness of, for example, 1 to 10 μm. In the semiconductor substrate 41, photodiodes PD are formed in pixel units by forming, for example, N-type (second conductive type) semiconductor regions 52 in pixel units in a P-type (first conductive type) semiconductor region 51. In this case, while the P-type semiconductor region 51 is constituted of a region of Si being a substrate material, the N-type semiconductor region 52 is constituted of a region of SiGe obtained by adding germanium (hereinafter, referred to as Ge) to Si. As will be described later, the SiGe region as the N-type semiconductor region 52 can be formed by injecting Ge into an Si region or by epitaxial growth. Note that the N-type semiconductor region 52 may be constituted of only Ge instead of being a SiGe region.

An upper surface of the semiconductor substrate 41 which is an upper side in FIG. 2 is a rear surface of the semiconductor substrate 41 which is a light incident surface on which light is incident. An anti-reflective film 43 is formed on the upper surface of the semiconductor substrate 41 on the rear surface side.

The anti-reflective film 43 has a laminated structure in which, for example, a fixed electric charge film and an oxide film are laminated and, for example, an insulated thin film having a high dielectric constant (High-k) according to an ALD (Atomic Layer Deposition) method may be used. Specifically, hafnium oxide (HfO₂), aluminum oxide (Al₂O₃), titanium oxide (TiO₂), STO (Strontium Titan Oxide), and the like can be used. In the example shown in FIG. 2, the anti-reflective film 43 is constructed by laminating a hafnium oxide film 53, an aluminum oxide film 54, and a silicon oxide film 55.

An inter-pixel light shielding film 45 that prevents incident light from being incident on adjacent pixels is formed at a boundary portion 44 of the adjacent pixels 10 (hereinafter, also referred to as a pixel boundary portion 44) on the semiconductor substrate 41 on the upper surface of the anti-reflective film 43. A material of the inter-pixel light shielding film 45 need only be a material that shields light and, for example, metal materials such as tungsten (W), aluminum (Al), or copper (Cu) can be used.

A planarizing film 46 is formed on the upper surface of the anti-reflective film 43 and on an upper surface of the inter-pixel light shielding film 45 by an insulating film using silicon oxide (SiO₂), silicon nitride (SiN), silicon oxynitride (SiON), or the like or by an organic material such as a resin.

An on-chip lens 47 is formed for each pixel on an upper surface of the planarizing film 46. The on-chip lens 47 is formed of, for example, a resin material such as a styrene resin, an acrylic resin, a styrene-acrylic copolymer resin, or a siloxane resin. Light collected by the on-chip lens 47 is efficiently incident on a photodiode PD.

A moth eye structure portion 71 in which fine irregularities are periodically formed is formed on the rear surface of the semiconductor substrate 41 and above a region where the photodiode PD is formed. In addition, the anti-reflective film 43 formed on an upper surface of the moth eye structure portion 71 of the semiconductor substrate 41 is also formed so as to have a moth eye structure in correspondence to the moth eye structure portion 71.

The moth eye structure portion 71 of the semiconductor substrate 41 is configured such that, for example, a plurality of quadrangular pyramid-like regions having substantially the same shape and substantially the same size are regularly provided (in a grid pattern).

The moth eye structure portion 71 is formed so as to have, for example, an inverted pyramid structure in which a plurality of quadrangular pyramid-like regions having vertices on a side of the photodiode PD are arrayed to be lined up regularly.

Alternatively, the moth eye structure portion 71 may have a forward pyramid structure in which a plurality of quadrangular pyramid-like regions having vertices on a side of the on-chip lens 47 are arrayed to be lined up regularly. The sizes and arrangement of the plurality of quadrangular pyramids may be formed randomly instead of being regularly arranged. In addition, each concave portion or each convex portion of each quadrangular pyramid of the moth eye structure portion 71 may have a certain degree of curvature and have a rounded shape. The moth eye structure portion 71 need only be structured so that a concave-convex structure is repeated periodically or randomly, and the shape of the concave portion or the convex portion is arbitrary.

In this manner, by forming the moth eye structure portion 71 on the light incident surface of the semiconductor substrate 41 as a diffraction structure that diffracts incident light, a sudden change in a refractive index at an interface of the substrate can be alleviated and an effect of reflected light can be reduced.

In the pixel boundary portion 44 on the rear surface side of the semiconductor substrate 41, an inter-pixel separation portion 61 separating adjacent pixels from each other is formed in a depth direction of the semiconductor substrate 41 from the rear surface side (the side of the on-chip lens 47) of the semiconductor substrate 41 until a predetermined depth in the substrate depth direction. Note that a depth in the substrate depth direction to which the inter-pixel separation portion 61 is formed can be set to an arbitrary depth, and the inter-pixel separation portion 61 may penetrate the semiconductor substrate 41 from the rear surface side to the front surface side so as to completely separate the semiconductor substrate 41 into pixel units. An outer circumferential portion including a bottom surface and a sidewall of the inter-pixel separation portion 61 is covered with the hafnium oxide film 53 which is a part of the anti-reflective film 43. The inter-pixel separation portion 61 prevents incident light from penetrating into an adjacent pixel 10 and keeps the incident light confined to an own pixel and, at the same time, prevents leakage of incident light from the adjacent pixel 10.

In the example shown in FIG. 2, although the silicon oxide film 55 that constitutes a part of laminated films as the anti-reflective film 43 and the inter-pixel separation portion 61 are constituted of a same material since the silicon oxide film 55 which is a material of an uppermost layer of the anti-reflective film 43 and the inter-pixel separation portion 61 are simultaneously formed by embedding the silicon oxide film 55 in a trench (a groove) having been dug from the rear surface side, the silicon oxide film 55 and the inter-pixel separation portion 61 need not necessarily be constituted of the same material. A material to be embedded in the trench (groove) dug from the rear surface side as the inter-pixel separation portion 61 may be, for example, a metal material such as tungsten (W), aluminum (Al), titanium (Ti), or titanium nitride (TiN).

On the other hand, two transfer transistors TRG1 and TRG2 are formed with respect to one photodiode PD formed in each pixel 10 on the front surface side of the semiconductor substrate 41 on which the multilayer wiring layer 42 is formed. In addition, floating diffusion regions FD1 and FD2 as electric charge holding portions for temporarily holding an electric charge transferred from the photodiode PD are constituted by a high-concentration N-type semiconductor region (N-type diffusion region) on the front surface side of the semiconductor substrate 41.

The multilayer wiring layer 42 is constituted by a plurality of metal films M and an interlayer insulating film 62 therebetween. While an example in which the multilayer wiring layer 42 is constituted by three layers from a first metal film M1 to a third metal film M3 is shown in FIG. 2, the number of layers of the metal films M are not limited to three.

A metal wiring made of copper, aluminum, or the like is formed as a light-shielding member 63 in a region which is positioned below a region where the photodiode PD is formed in the first metal film M1 being closest to the semiconductor substrate 41 among the plurality of metal films M of the multilayer wiring layer 42 or, in other words, in a region of which at least a portion overlaps with the region where the photodiode PD is formed in a plan view.

The light-shielding member 63 shields infrared light incident into the semiconductor substrate 41 from a light incident surface through the on-chip lens 47 and having passed through the semiconductor substrate 41 without being photoelectrically converted in the semiconductor substrate 41 by the first metal film M1 closest to the semiconductor substrate 41 and prevents the infrared light from passing through the second metal film M2 and the third metal film M3 positioned below the first metal film M1. Due to such a light shielding function, infrared light having passed through the semiconductor substrate 41 without being photoelectrically converted in the semiconductor substrate 41 can be prevented from being dispersed by the metal film M below the first metal film M1 and being incident on nearby pixels. Accordingly, light can be prevented from being erroneously detected in the nearby pixels.

In addition, the light-shielding member 63 also has a function of causing infrared light, having been incident into the semiconductor substrate 41 from a light incident surface through the on-chip lens 47 and having passed through the semiconductor substrate 41 without being photoelectrically converted in the semiconductor substrate 41, to be reflected by the light-shielding member 63 and once again incident into the semiconductor substrate 41. Therefore, the light-shielding member 63 can also be described as being a reflecting member. According to such a reflection function, an amount of infrared light that is photoelectrically converted in the semiconductor substrate 41 can be increased and quantum efficiency (QE) or, in other words, sensitivity of the pixel 10 with respect to infrared light can be improved.

Besides a metal material, the light-shielding member 63 may form a structure for reflecting or shielding light using a polysilicon film or an oxide film.

Furthermore, instead of being constituted by a single-layer metal film M, the light-shielding member 63 may be constituted by a plurality of metal films M such as being formed in a grid pattern by the first metal film M1 and the second metal film M2.

A wiring capacitance 64 is formed in, for example, a predetermined metal film M among the plurality of metal films M of the multilayer wiring layer 42 such as the second metal film M2 by forming a pattern in, for example, a comb tooth shape. While the light-shielding member 63 and the wiring capacitance 64 may be formed in a same layer (metal film M), in a case where the light-shielding member 63 and the wiring capacitance 64 are formed in different layers, the wiring capacitance 64 is to be formed in a layer farther from the semiconductor substrate 41 than the light-shielding member 63. In other words, the light-shielding member 63 is to be formed closer to the semiconductor substrate 41 than the wiring capacitance 64.

As described above, the light-receiving element 1 has a backside illumination structure in which the semiconductor substrate 41 being a semiconductor layer is arranged between the on-chip lens 47 and the multilayer wiring layer 42 and incident light is incident on the photodiode PD from a rear surface side where the on-chip lens 47 is formed.

In addition, the pixel 10 includes the two transfer transistors TRG1 and TRG2 with respect to the photodiode PD provided in each pixel and is configured to be capable of distributing an electric charge (electrons) generated by being photoelectrically converted in the photodiode PD to the floating diffusion region FD1 or FD2.

Furthermore, by forming the inter-pixel separation portion 61 in the pixel boundary portion 44, the pixel 10 prevents incident light from penetrating into an adjacent pixel 10 and keeps the incident light confined to an own pixel and, at the same time, prevents leakage of incident light from the adjacent pixel 10. In addition, by providing the light-shielding member 63 in a metal film M below the region where the photodiode PD is formed, infrared light having passed through the semiconductor substrate 41 without being photoelectrically converted in the semiconductor substrate 41 is caused to be reflected by the light-shielding member 63 and once again incident into the semiconductor substrate 41.

In addition, in the pixel 10, the N-type semiconductor region 52 being a photoelectric conversion region is formed by a SiGe region or a Ge region. Since SiGe and Ge have a narrower bandgap than Si, quantum efficiency of near-infrared light can be enhanced.

Due to the above-described configuration, the light-receiving element 1 including the pixel 10 according to the first configuration example is capable of increasing an amount of infrared light photoelectrically converted in the semiconductor substrate 41 and improve quantum efficiency (QE) or, in other words, sensitivity with respect to infrared light.

### <3. Circuit Configuration Example of Pixel>

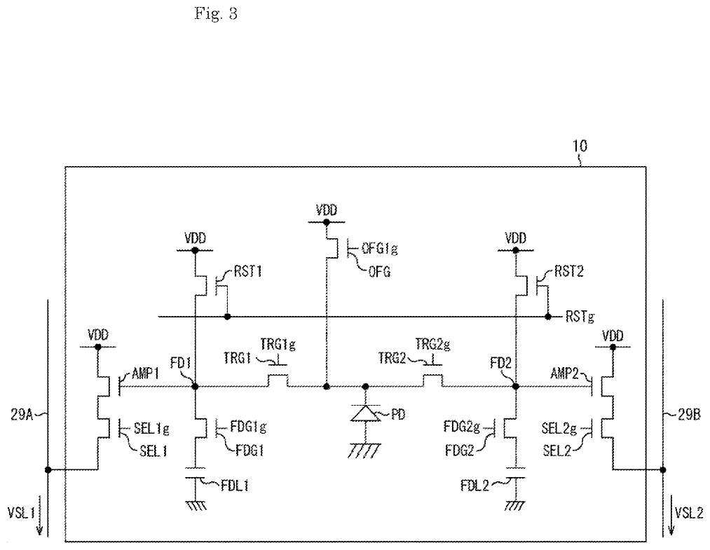

FIG. 3 shows a circuit configuration of each of the pixels 10 which are two-dimensionally arranged in the pixel array portion 21.

The pixel 10 includes the photodiode PD as a photoelectric conversion element. In addition, the pixel 10 includes two each of the transfer transistor TRG, the floating diffusion region FD, the additional capacitor FDL, the switching transistor FDG, the amplifying transistor AMP, the reset transistor RST, and the selective transistor SEL. Furthermore, the pixel 10 includes an electric charge discharging transistor OFG.

Here, in a case where the transfer transistors TRG, the floating diffusion regions FD, the additional capacitors FDL, the switching transistors FDG, the amplifying transistors AMP, the reset transistors RST, and the selective transistors SEL of which two each are provided in the pixel 10 are distinguished from each other, the designations transfer transistors TRG1 and TRG2, floating diffusion regions FD1 and FD2, additional capacitors FDL1 and FDL2, switching transistors FDG1 and FDG2, amplifying transistors AMP1 and AMP2, reset transistors RST1 and RST2, and selective transistors SEL1 and SEL2 will be used as shown in FIG. 3.

The transfer transistor TRG, the switching transistor FDG, the amplifying transistor AMP, the selective transistor SEL, the reset transistor RST, and the electric charge discharging transistor OFG are constituted by, for example, an N-type MOS transistor.

The transfer transistor TRG1 assumes a conductive state in response to a transfer drive signal TRG1g supplied to a gate electrode assuming an active state and transfers an electric charge accumulated in the photodiode PD to the floating diffusion region FD1. The transfer transistor TRG2 assumes a conductive state in response to a transfer drive signal TRG2g supplied to a gate electrode assuming an active state and transfers an electric charge accumulated in the photodiode PD to the floating diffusion region FD2.

The floating diffusion regions FD1 and FD2 are electric charge holding portions that temporarily hold the electric charge transferred from the photodiode PD.

The switching transistor FDG1 assumes a conductive state in response to an FD drive signal FDG1g supplied to a gate electrode assuming an active state and connects the additional capacitor FDL1 to the floating diffusion region FD1. The switching transistor FDG2 assumes a conductive state in response to an FD drive signal FDG2g supplied to a gate electrode assuming an active state and connects the additional capacitor FDL2 to the floating diffusion region FD2. The additional capacitors FDL1 and FDL2 are formed by the wiring capacitance 64 shown in FIG. 2.

The reset transistor RST1 assumes a conductive state in response to a reset drive signal RSTg supplied to a gate electrode assuming an active state and resets a potential of the floating diffusion region FD1. The reset transistor RST2 assumes a conductive state in response to a reset drive signal RSTg supplied to a gate electrode assuming an active state and resets a potential of the floating diffusion region FD2. Note that, when the reset transistors RST1 and RST2 assume an active state, the switching transistors FDG1 and FDG2 simultaneously assume an active state and the additional capacitors FDL1 and FDL2 are also reset.

For example, in a state of high illuminance with a large amount of incident light, the vertical driving portion 22 causes the switching transistors FDG1 and FDG2 to assume an active state, connects the floating diffusion region FD1 and the additional capacitor FDL1 to each other, and connects the floating diffusion region FD2 and the additional capacitor FDL2 to each other. Accordingly, a larger amount of electric charge can be accumulated when the illuminance is high.

On the other hand, in a state of low illuminance with a small amount of incident light, the vertical driving portion 22 causes the switching transistors FDG1 and FDG2 to assume an inactive state and respectively disconnects the additional capacitors FDL1 and FDL2 from the floating diffusion regions FD1 and FD2. Accordingly, conversion efficiency can be improved.

The electric charge discharging transistor OFG assumes a conductive state in response to a discharge drive signal OFG1g supplied to a gate electrode assuming an active state and discharges an electric charge accumulated in the photodiode PD.

By having a source electrode connected to a vertical signal line 29A through the selective transistor SEL1, the amplifying transistor AMP1 is connected to a constant current source (not illustrated) and constitutes a source follower circuit. By having a source electrode connected to a vertical signal line 29B through the selective transistor SEL2, the amplifying transistor AMP2 is connected to a constant current source (not illustrated) and constitutes a source follower circuit.

The selective transistor SEL1 is connected between the source electrode of the amplifying transistor AMP1 and the vertical signal line 29A. The selective transistor SEL1 assumes a conductive state in response to a selection signal SEL1g supplied to a gate electrode assuming an active state and outputs a pixel signal VSL1 output from the amplifying transistor AMP1 to the vertical signal line 29A.

The selective transistor SEL2 is connected between the source electrode of the amplifying transistor AMP2 and the vertical signal line 29B. The selective transistor SEL2 assumes a conductive state in response to a selection signal SEL2g supplied to a gate electrode assuming an active state and outputs a pixel signal VSL2 output from the amplifying transistor AMP2 to the vertical signal line 29B.

The transfer transistors TRG1 and TRG2, the switching transistors FDG1 and FDG2, the amplifying transistors AMP1 and AMP2, the selective transistors SEL1 and SEL2, and the electric charge discharging transistor OFG of the pixel 10 are controlled by the vertical driving portion 22.

While the additional capacitors FDL1 and FDL2 and the switching transistors FDG1 and FDG2 that control connections of the additional capacitors FDL1 and FDL2 may be omitted in the pixel circuit shown in FIG. 3, a high dynamic range can be secured by providing an additional capacitor FDL and appropriately using the additional capacitor FDL according to the amount of incident light.

Operations of the pixel 10 shown in FIG. 3 will be briefly described.

First, before light reception is started, a reset operation for resetting an electric charge of the pixel 10 is performed in all pixels. In other words, the electric charge discharging transistor OFG, the reset transistors RST1 and RST2, and the switching transistors FDG1 and FDG2 are turned on, and electric charges accumulated in the photodiode PD, the floating diffusion regions FD1 and FD2, and the additional capacitors FDL1 and FDL2 are discharged.

After the accumulated electric charges are discharged, light reception is started in all pixels. In a light receiving period, the transfer transistors TRG1 and TRG2 are alternately driven. In other words, in a first period, the transfer transistor TRG1 is controlled to be turned on and the transfer transistor TRG2 is controlled to be turned off. In the first period, an electric charge generated in the photodiode PD is transferred to the floating diffusion region FD1. In a second period subsequent to the first period, the transfer transistor TRG1 is controlled to be turned off and the transfer transistor TRG2 is controlled to be turned on. In the second period, an electric charge generated in the photodiode PD is transferred to the floating diffusion region FD2. Accordingly, an electric charge generated in the photodiode PD is alternately distributed to the floating diffusion regions FD1 and FD2 and accumulated therein.

In addition, when the light receiving period ends, each pixel 10 of the pixel array portion 21 is line-sequentially selected. In the selected pixel 10, the selective transistors SEL1 and SEL2 are turned on. Accordingly, an electric charge accumulated in the floating diffusion region FD1 is output to the column processing portion 23 via the vertical signal line 29A as a pixel signal VSL1. An electric charge accumulated in the floating diffusion region FD2 is output to the column processing portion 23 via the vertical signal line 29B as a pixel signal VSL2.

One light receiving operation is completed in this manner and a next light receiving operation that commences with a reset operation is executed.

Reflected light received by the pixel 10 is delayed in accordance with a distance to an object from a timing when a light source emits light. Since a distribution ratio of an electric charge accumulated in the two floating diffusion regions FD1 and FD2 changes depending on a delay time in accordance with a distance to the object, the distance to the object can be obtained from the distribution ratio of the electric charge accumulated in the two floating diffusion regions FD1 and FD2.

### <4. Plan View of Pixel>

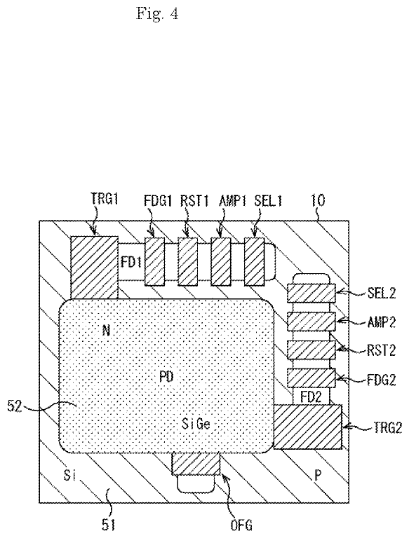

FIG. 4 is a plan view showing an arrangement example of the pixel circuit shown in FIG. 3.

A transverse direction in FIG. 4 corresponds to a row direction (horizontal direction) in FIG. 1 and a longitudinal direction corresponds to a column direction (vertical direction) in FIG. 1.

As shown in FIG. 4, the photodiode PD is formed by an N-type semiconductor region 52 in a region of a central part of a rectangular pixel 10 and the region constitutes a SiGe region.

The transfer transistor TRG1, the switching transistor FDG1, the reset transistor RST1, the amplifying transistor AMP1, and the selective transistor SEL1 are linearly arranged side by side on the outer side of the photodiode PD and along one predetermined side among four sides of the rectangular pixel 10, and the transfer transistor TRG2, the switching transistor FDG2, the reset transistor RST2, the amplifying transistor AMP2, and the selective transistor SEL2 are linearly arranged side by side along another side among the four sides of the rectangular pixel 10.

Furthermore, the electric charge discharging transistor OFG is arranged at a side that differs from the two sides of the pixel 10 where the transfer transistors TRG, the switching transistors FDG, the reset transistors RST, the amplifying transistors AMP, and the selective transistors SEL are formed.

Note that the arrangement of the pixel circuit is not limited to the example shown in FIG. 3 and that other arrangements can also be adopted.

### <5. Another Circuit Configuration Examples of Pixel>

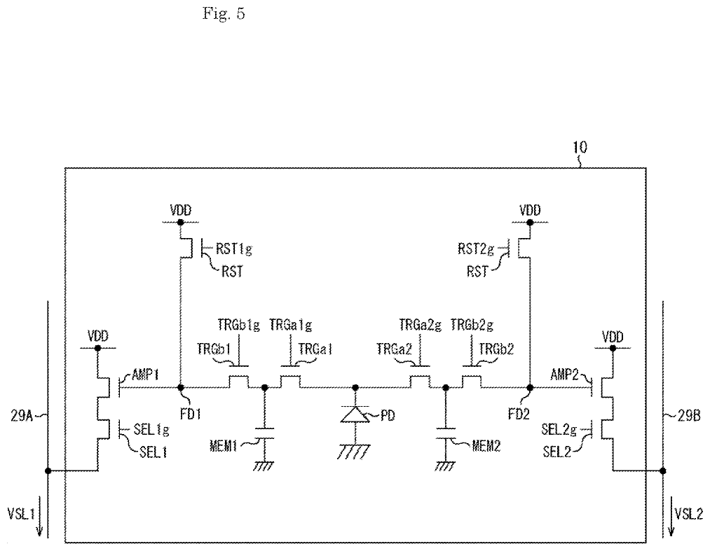

FIG. 5 shows another circuit configuration example of the pixel 10.

In FIG. 5, portions corresponding to those in FIG. 3 are denoted by the same reference signs and descriptions of the portions will be appropriately omitted.

The pixel 10 includes the photodiode PD as a photoelectric conversion element. In addition, the pixel 10 includes two each of a first transfer transistor TRGa, a second transfer transistor TRGb, a memory MEM, the floating diffusion region FD, the reset transistor RST, the amplifying transistor AMP, and the selective transistor SEL.

Here, in a case where the first transfer transistor TRGa, the second transfer transistor TRGb, the memory MEM, the floating diffusion region FD, the reset transistor RST, the amplifying transistor AMP, and the selective transistor SEL of which two each are provided in the pixel 10 are distinguished from each other, they are respectively referred to as first transfer transistors TRGa1 and TRGa2, second transfer transistors TRGb1 and TRGb2, transfer transistors TRG1 and TRG2, memories MEM1 and MEM2, floating diffusion regions FD1 and FD2, amplifying transistors AMP1 and AMP2, and selective transistors SEL1 and SEL2 as shown in FIG. 5.

Therefore, comparing the pixel circuit shown in FIG. 3 with the pixel circuit shown in FIG. 5, the transfer transistors TRG are changed to two types, namely, a first transfer transistor TRGa and a second transfer transistor TRGb, and the memories MEM are added. In addition, the additional capacitor FDL and the switching transistor FDG are omitted.

The first transfer transistor TRGa, the second transfer transistor TRGb, the reset transistor RST, the amplifying transistor AMP, and selective transistor SEL are constituted by, for example, an N-type MOS transistor.

While an electric charge generated by the photodiode PD is transferred to the floating diffusion regions FD1 and FD2 and is held therein in the pixel circuit shown in FIG. 3, in the pixel circuit shown in FIG. 5, the electric charge is transferred to the memories MEM1 and MEM2 newly provided as electric charge holding portions and is held therein.

In other words, the first transfer transistor TRGa1 transfers an electric charge accumulated in the photodiode PD to the memory MEM1 by changing to a conductive state in response to a change of a first transfer drive signal TRGa1g supplied to a gate electrode to an active state. The first transfer transistor TRGa2 transfers an electric charge accumulated in the photodiode PD to the memory MEM2 by changing to a conductive state in response to a change of a first transfer drive signal TRGa2g supplied to a gate electrode to an active state.

In addition, the second transfer transistor TRGb1 transfers an electric charge held in the MEM1 to the floating diffusion region FD1 by changing to a conductive state in response to a change of a second transfer drive signal TRGb1g supplied to a gate electrode to an active state. The second transfer transistor TRGb2 transfers an electric charge held in the MEM2 to the floating diffusion region FD2 by changing to a conductive state in response to a change of a second transfer drive signal TRGb2g supplied to a gate electrode to an active state.

The reset transistor RST1 resets the potential of the floating diffusion region FD1 by changing to a conductive state in response to a change of a reset drive signal RST1g supplied to a gate electrode to an active state. The reset transistor RST2 resets the potential of the floating diffusion region FD2 by changing to a conductive state in response to a change of a reset drive signal RST2g supplied to a gate electrode to an active state. Note that, when the reset transistors RST1 and RST2 change to an active state, the second transfer transistors TRGb1 and TRGb2 simultaneously change to an active state and the memories MEM1 and MEM2 are also reset.

In the pixel circuit shown in FIG. 5, an electric charge generated by the photodiode PD is distributed to the memories MEM1 and MEM2 and is accumulated therein. In addition, the electric charges held in the memories MEM1 and MEM2 are respectively transferred to the floating diffusion regions FD1 and FD2 at a timing when the electric charges are read out and are output from the pixel 10.

### <6. Plan View of Pixel>

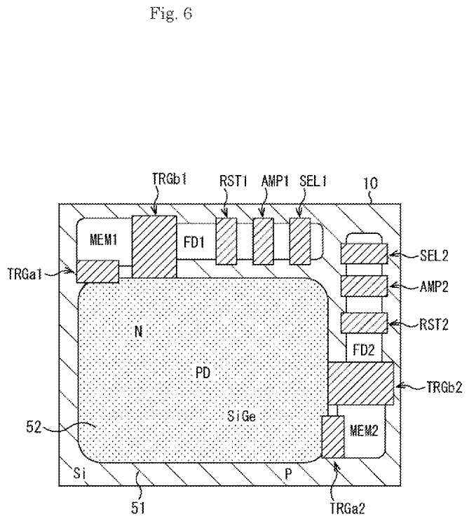

FIG. 6 is a plan view illustrating an arrangement example of the pixel circuit shown in FIG. 5.

A transverse direction in FIG. 6 corresponds to a row direction (horizontal direction) in FIG. 1 and a longitudinal direction corresponds to a column direction (vertical direction) in FIG. 1.

As shown in FIG. 6, an N-type semiconductor region 52 as the photodiode PD in the rectangular pixel 10 is formed of a SiGe region.

The first transfer transistor TRGa1, the second transfer transistor TRGb1, the reset transistor RST1, the amplifying transistor AMP1, and the selective transistor SEL1 are linearly arranged side by side on the outer side of the photodiode PD and along one predetermined side among four sides of the rectangular pixel 10, and the first transfer transistor TRGa2, the second transfer transistor TRGb2, the reset transistor RST2, the reset transistor RST2, the amplifying transistor AMP2, and the selective transistor SEL2 are linearly arranged side by side along another side among the four sides of the rectangular pixel 10. The memories MEM1 and MEM2 are formed of, for example, an embedded N-type diffusion region.

Note that the arrangement of the pixel circuit is not limited to the example shown in FIG. 5 and that other arrangements can also be adopted.

### <7. Formation Method of GeSi Region>

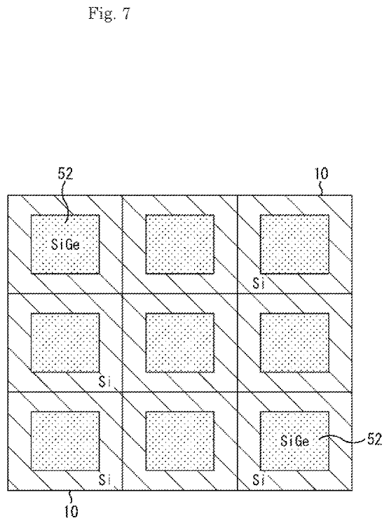

FIG. 7 is a plan view showing an arrangement example of 3×3 pixels 10 among the plurality of pixels 10 of the pixel array portion 21.

When only the N-type semiconductor region 52 of each pixel 10 is formed of a SiGe region, an arrangement in which the SiGe region is separated into pixel units such as that shown in FIG. 7 is obtained when considering an entire region of the pixel array portion 21.

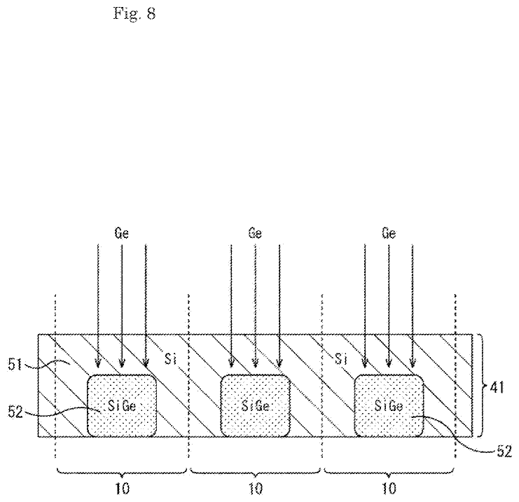

FIG. 8 is a sectional view of the semiconductor substrate 41 for explaining a first formation method in which the N-type semiconductor region 52 is formed of a SiGe region.

In the first formation method, as shown in FIG. 8, the N-type semiconductor region 52 can be formed as a SiGe region by performing selective ion implantation of Ge using a mask in a portion to become the N-type semiconductor region 52 of the semiconductor substrate 41 that is an Si region. Regions other than the N-type semiconductor region 52 of the semiconductor substrate 41 become P-type semiconductor regions 51 made of an Si region.

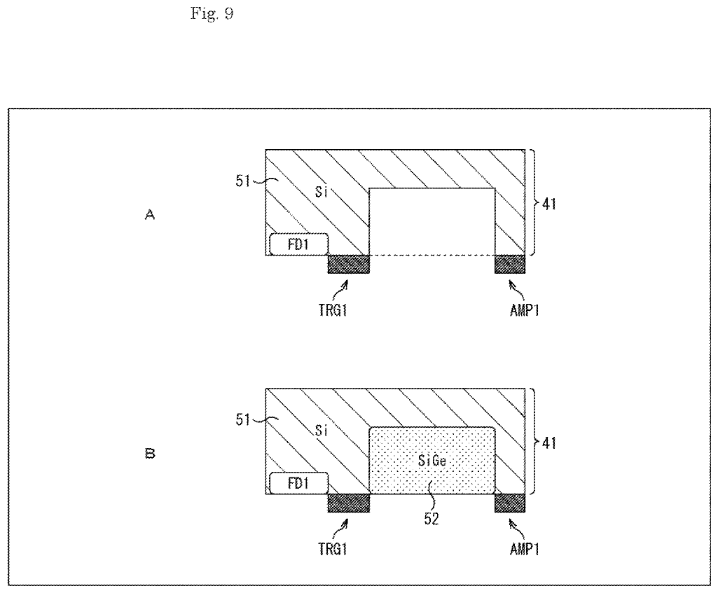

FIG. 9 is a sectional view of the semiconductor substrate 41 for explaining a second formation method in which the N-type semiconductor region 52 is formed of a SiGe region.

In the second formation method, first, as shown in A in FIG. 9, a portion of an Si region to become the N-type semiconductor region 52 of the semiconductor substrate 41 is removed. Next, as shown in B in FIG. 9, the N-type semiconductor region 52 is formed of a SiGe region by forming a SiGe layer by epitaxial growth in the removed region.

Note that an arrangement of pixel transistors in FIG. 9 differs from the arrangement shown in FIG. 4 and represents an example in which the amplifying transistor AMP1 is arranged in a vicinity of the N-type semiconductor region 52 formed of a SiGe region.

As described above, the N-type semiconductor region 52 to be a SiGe region can be formed by any of the first formation method in which ion implantation of Ge is performed in an Si region and the second formation method in which a SiGe layer is epitaxially grown. A similar formation method can be adopted when forming the N-type semiconductor region 52 of a Ge region.

### <8. Modification of First Configuration Example>

While the pixel 10 according to the first configuration example described above is configured such that only the N-type semiconductor region 52 that is a photoelectric conversion region in the semiconductor substrate 41 is formed of a SiGe region or a Ge region, the P-type semiconductor region 51 under the gate of the transfer transistor TRG may also be formed of a P-type SiGe region or Ge region.

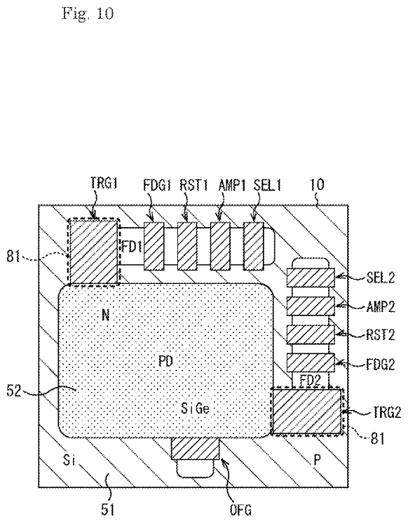

FIG. 10 is diagram once again showing a planar arrangement shown in FIG. 4 of the pixel circuit shown in FIG. 3, and a P-type region 81 under the gate of the transfer transistors TRG1 and TRG2 indicated by dashed lines in FIG. 10 is formed of a SiGe region or a Ge region. Forming a channel region of the transfer transistors TRG1 and TRG2 by a SiGe region or a Ge region enables channel mobility to be increased in the transfer transistors TRG1 and TRG2 that are driven at high speed.

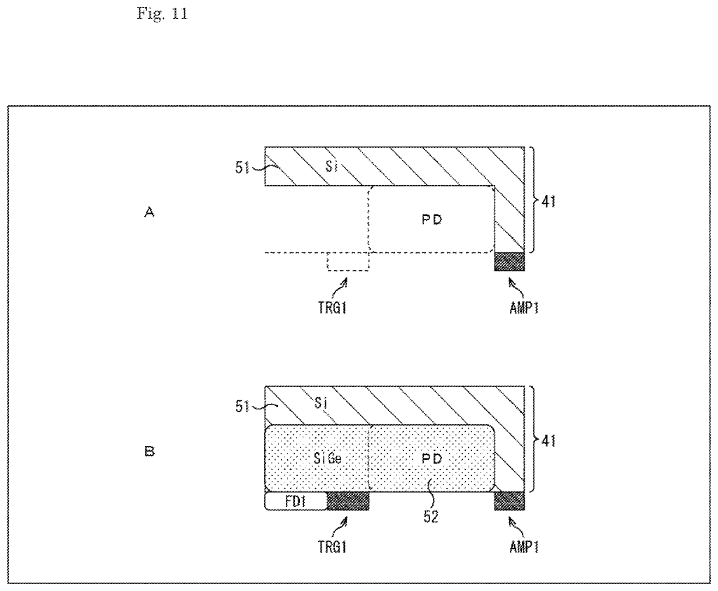

When the channel region of the transfer transistors TRG1 and TRG2 is made a SiGe region using epitaxial growth, first, as shown in A in FIG. 11, the portion of the semiconductor substrate 41 in which the N-type semiconductor region 52 is to be formed and a portion below the gate of the transfer transistors TRG1 and TRG2 are removed. In addition, as shown in B in FIG. 11, by forming a SiGe layer by epitaxial growth in the removed regions, the N-type semiconductor region 52 and the region below the gate of the transfer transistors TRG1 and TRG2 are formed of a SiGe region.

In this case, forming the floating diffusion regions FD1 and FD2 in the formed SiGe regions is problematic in that a dark current generated from the floating diffusion regions FD increases. Therefore, when a region in which the transfer transistor TRG is formed is made a SiGe region, as shown in B in FIG. 11, a structure is adopted in which an Si layer is further formed by epitaxial growth on a formed SiGe layer to form a high-concentration N-type semiconductor region (N-type diffusion region) to be used as the floating diffusion region FD. Accordingly, a dark current from the floating diffusion region FD can be suppressed.

The P-type semiconductor region 51 under the gate of the transfer transistor TRG can be made a SiGe region by selective ion implantation using a mask instead of epitaxial growth, and similarly in this case, the floating diffusion regions FD1 and FD2 can be created by further forming an Si layer by epitaxial growth on the formed SiGe layer.

### <9. Substrate Configuration Example of Light-Receiving Element>

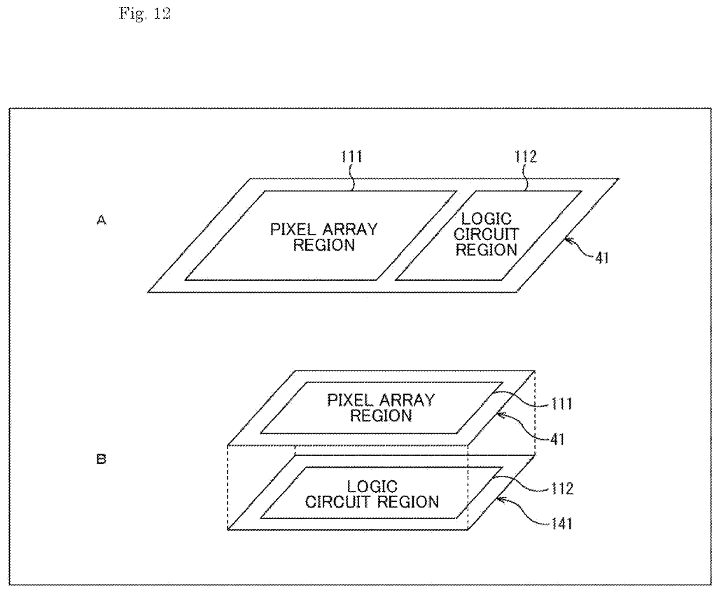

FIG. 12 is a schematic perspective view showing a substrate configuration example of the light-receiving element 1.

The light-receiving element 1 may be formed on a single semiconductor substrate or formed on a plurality of semiconductor substrates.

A in FIG. 12 shows a schematic configuration example in a case where the light-receiving element 1 is formed on a single semiconductor substrate.

When the light-receiving element 1 is formed on a single semiconductor substrate, as shown in A of FIG. 12, a pixel array region 111 corresponding to the pixel array portion 21 and a logic circuit region 112 corresponding to circuits other than the pixel array portion 21 such as control circuits including the vertical driving portion 22 and the horizontal driving portion 24 and arithmetic circuits including the column processing portion 23 and the signal processing portion 26 are lined up in a planar direction and formed on the single semiconductor substrate 41. The sectional configuration shown in FIG. 2 represents this single-substrate configuration.

On the other hand, B in FIG. 12 shows a schematic configuration example in a case where the light-receiving element 1 is formed on a plurality of semiconductor substrates.

When the light-receiving element 1 is formed on a plurality of semiconductor substrates, as shown in B of FIG. 12, while the pixel array region 111 is formed on the semiconductor substrate 41, the logic circuit region 112 is formed on another semiconductor substrate 141, and the light-receiving element 1 is constructed by laminating the semiconductor substrate 41 and the semiconductor substrate 141.

In the following description, for the sake of brevity, the semiconductor substrate 41 will be referred to as a first substrate 41 and the semiconductor substrate 141 will be referred to as a second substrate 141 in the case of a laminated structure.

### <10. Sectional View of Pixel in Case of Laminated Structure>

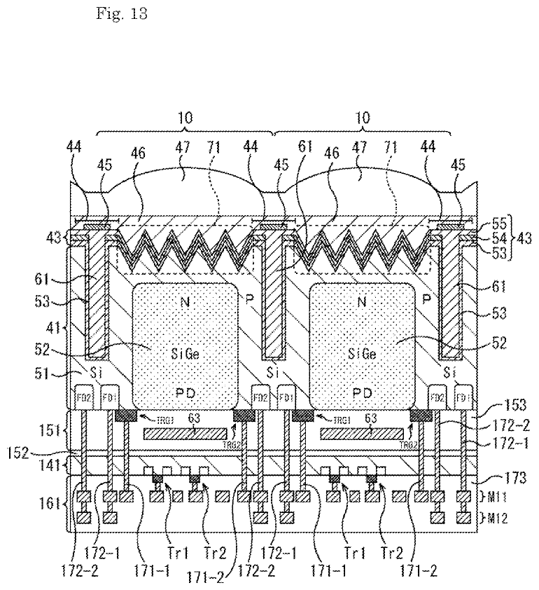

FIG. 13 is a sectional view of the pixel 10 when the light-receiving element 1 is constituted by a laminated structure of two substrates.

In FIG. 13, portions corresponding to those in the first configuration example shown in FIG. 2 are denoted by the same reference signs and descriptions of such portions will be appropriately omitted.

As described with reference to FIG. 12, the laminated structure shown in FIG. 13 is constructed using two semiconductor substrates, the first substrate 41 and the second substrate 141.

The laminated structure shown in FIG. 13 is similar to the first configuration example shown in FIG. 2 in that the inter-pixel light shielding film 45, the planarizing film 46, the on-chip lens 47, and the moth eye structure portion 71 are formed on a light incident surface side of the first substrate 41. Another similarity to the first configuration example shown in FIG. 2 is that the inter-pixel separation portion 61 is formed in the pixel boundary portion 44 on a rear surface side of the first substrate 41.

In addition, another similarity is that the photodiodes PD are formed on the first substrate 41 in pixel units and that two transfer transistors TRG1 and TRG2 and the floating diffusion regions FD1 and FD2 as electric charge holding portions are formed on the front surface side of the first substrate 41.

On the other hand, a difference from the first configuration example shown in FIG. 2 is that an insulating layer 153 that is a part of a wiring layer 151 being a front surface side of the first substrate 41 is bonded to an insulating layer 152 of the second substrate 141.

The wiring layer 151 of the first substrate 41 includes at least a metal film M of a single layer, and the light-shielding member 63 is formed using the metal film M in a region positioned below the region where the photodiode PD is formed.

Pixel transistors Tr1 and Tr2 are formed at an interface on a side opposite to the insulating layer 152 side that is a bonding surface side of the second substrate 141. The pixel transistors Tr1 and Tr2 are, for example, the amplifying transistor AMP, the selective transistor SEL, or the like.

In other words, while all pixel transistors including the transfer transistor TRG, the switching transistor FDG, the amplifying transistor AMP, and the selective transistor SEL are formed on the semiconductor substrate 41 in the first configuration example that is constructed using only one semiconductor substrate 41 (first substrate 41), in the light-receiving element 1 with a laminated structure of two semiconductor substrates, pixel transistors other than the transfer transistor TRG or, in other words, the switching transistor FDG, the amplifying transistor AMP, and the selective transistor SEL are formed on the second substrate 141.

A wiring layer 161 including at least two layers of the metal film M is formed on a side opposite to the side of the first substrate 41 of the second substrate 141. The wiring layer 161 includes a first metal film M11, a second metal film M12, and an insulating layer 173.

A transfer drive signal TRG1g that controls the transfer transistor TRG1 is supplied from the first metal film M11 of the second substrate 141 to a gate electrode of the transfer transistor TRG1 of the first substrate 41 by a TSV (Through Silicon Via) 171-1 that penetrates the second substrate 141. A transfer drive signal TRG2g that controls the transfer transistor TRG2 is supplied from the first metal film M11 of the second substrate 141 to a gate electrode of the transfer transistor TRG2 of the first substrate 41 by a TSV 171-2 that penetrates the second substrate 141.

Similarly, an electric charge accumulated in the floating diffusion region FD1 is transferred from the side of the first substrate 41 to the first metal film M11 of the second substrate 141 by a TSV 172-1 that penetrates the second substrate 141. An electric charge accumulated in the floating diffusion region FD2 is also transferred from the side of the first substrate 41 to the first metal film M11 of the second substrate 141 by a TSV 172-2 that penetrates the second substrate 141.

The wiring capacitance 64 is formed in a region (not illustrated) of the first metal film M11 or the second metal film M12. The metal film M having the wiring capacitance 64 formed therein is formed so as to have a high wiring density for the purpose of capacity formation, and the metal film M connected to a gate electrode of the transfer transistor TRG, the switching transistor FDG, or the like is formed so as to have a low wiring density for the purpose of reducing an induced current. A configuration may be adopted in which a wiring layer (metal film M) connected to the gate electrode is different for each pixel transistor.

As described above, the pixel 10 can be constructed by stacking two semiconductor substrates, namely, the first substrate 41 and the second substrate 141, and the pixel transistors other than the transfer transistor TRG are formed on the second substrate 141 that differs from the first substrate 41 including a photoelectric conversion portion. In addition, the vertical driving portion 22 and the pixel drive line 28 that control the driving of the pixels 10, the vertical signal line 29 that transmits a pixel signal, and the like are also formed on the second substrate 141. Accordingly, pixels can be miniaturized and a degree of freedom in BEOL (Back End of Line) design is also increased.

Even in the pixel 10 shown in FIG. 13, adopting a backside illumination pixel structure enables a sufficient numerical aperture to be secured as compared to a frontside illumination pixel structure and quantum efficiency (QE)×numerical aperture (FF) can be maximized.

In addition, by providing the light-shielding member (reflecting member) 63 in a region that overlaps with a region where the photodiode PD is formed on the wiring layer 151 closest to the first substrate 41, infrared light having passed through the semiconductor substrate 41 without being photoelectrically converted in the semiconductor substrate 41 can be reflected by the light-shielding member 63 and made to be incident into the semiconductor substrate 41 once again. Furthermore, infrared light having passed through the semiconductor substrate 41 without being photoelectrically converted in the semiconductor substrate 41 can be prevented from being incident on a side of the second substrate 141.

Even in the pixel 10 shown in FIG. 13, since the N-type semiconductor region 52 that constitutes the photodiode PD is formed of a SiGe region or a Ge region, quantum efficiency of near-infrared light can be increased.

With the pixel structure described above, an amount of infrared light that is photoelectrically converted in the semiconductor substrate 41 can be increased, quantum efficiency (QE) can be improved, and sensitivity of a sensor can be enhanced.

### <11. Laminated Structure of Three Substrates>

While FIG. 13 represents an example in which the light-receiving element 1 is constituted of two semiconductor substrates, the light-receiving element 1 may be constituted of three semiconductor substrates.

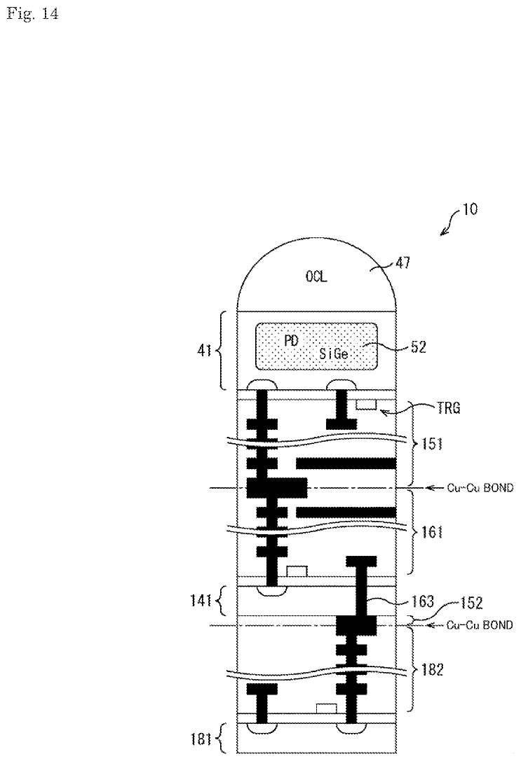

FIG. 14 shows a schematic sectional view of the light-receiving element 1 formed by laminating three semiconductor substrates.

In FIG. 14, portions corresponding to those in FIG. 12 are denoted by the same reference signs and descriptions of the portions will be appropriately omitted.

The pixel 10 shown in FIG. 14 is constructed by stacking, on the first substrate 41 and the second substrate 141, yet another semiconductor substrate 181 (hereinafter, referred to as a third substrate 181).

At least the photodiode PD and the transfer transistor TRG are formed on the first substrate 41. The N-type semiconductor region 52 that constitutes the photodiode PD is formed of a SiGe region or a Ge region.

Pixel transistors other than the transfer transistor TRG including the amplifying transistor AMP, the reset transistor RST, and the selective transistor SEL are formed on the second substrate 141.

A signal circuit for processing a pixel signal output from the pixel 10 such as the column processing portion 23 or the signal processing portion 26 is formed on the third substrate 181.

The first substrate 41 is a backside illumination substrate in which the on-chip lens 47 is formed on a rear surface side opposite to a front surface side on which the wiring layer 151 is formed and which light is incident from the rear surface side of the first substrate 41.

The wiring layer 151 of the first substrate 41 is bonded to the wiring layer 161 on the front surface side of the second substrate 141 by a Cu—Cu bond.

The second substrate 141 and the third substrate 181 are bonded to each other by a Cu—Cu bond between a Cu film formed on a wiring layer 182 on the front surface side of the third substrate 181 and a Cu film formed on an insulating layer 152 of the second substrate 141. The wiring layer 161 of the second substrate 141 and the wiring layer 182 of the third substrate 181 are electrically connected via a through electrode 163.

While the wiring layer 161 on the front surface side of the second substrate 141 is bonded so as to face the wiring layer 151 of the first substrate 41 in the example shown in FIG. 14, the second substrate 141 may be turned upside down and the wiring layer 161 of a second substrate 141B may be bonded so as to face the wiring layer 182 of the third substrate 181.

### <12. Configuration Example of 4-Tap Pixel>

The pixel 10 described above has a pixel structure called 2-tap which includes, with respect to one photodiode PD, two transfer transistors TRG1 and TRG2 as transfer gates and two floating diffusion regions FD1 and FD2 as electric charge holding portions, and which distributes an electric charge generated by the photodiode PD to the two floating diffusion regions FD1 and FD2.

By comparison, the pixel 10 can also adopt a 4-tap pixel structure which includes, with respect to one photodiode PD, four transfer transistors TRG1 to TRG4 and four floating diffusion regions FD1 to FD4 and which distributes an electric charge generated by the photodiode PD to the four floating diffusion regions FD1 to FD4.

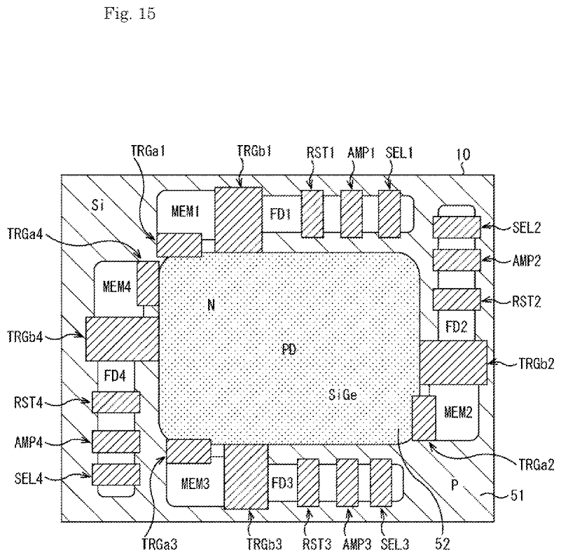

FIG. 15 is a plan view when the memory MEM-holding pixel 10 shown in FIGS. 5 and 6 adopts a 4-tap pixel structure.

The pixel 10 includes four each of a first transfer transistor TRGa, a second transfer transistor TRGb, a reset transistor RST, an amplifying transistor AMP, and a selective transistor SEL.

A set made up of the first transfer transistor TRGa, the second transfer transistor TRGb, the reset transistor RST, the amplifying transistor AMP, and the selective transistor SEL are linearly arranged side by side along each of the four sides of the rectangular pixel 10 on an outer side of the photodiode PD.

In FIG. 15, each set of the first transfer transistor TRGa, the second transfer transistor TRGb, the reset transistor RST, the amplifying transistor AMP, and the selective transistor SEL arranged along each of the four sides of the rectangular pixel 10 are distinguished by attaching any of the numbers 1 to 4.

When the pixel 10 has a 2-tap structure, drive is performed to distribute a generated electric charge to the two floating diffusion regions FD by shifting phases (light reception timings) by 180 degrees between a first tap and a second tap. By comparison, when the pixel 10 has a 4-tap pixel structure, drive can be performed to distribute a generated electric charge to the four floating diffusion regions FD by shifting phases (light reception timings) by 90 degrees among first to fourth taps. In addition, a distance to an object can be obtained based on a distribution ratio of electric charges accumulated in the four floating diffusion regions FD.

As described above, besides a structure in which an electric charge generated by the photodiode PD is distributed by two taps, the pixel 10 can adopt a structure that distributes the electric charge by four taps and, besides two taps, the electric charge can be distributed by three or more taps. Even when the pixel 10 adopts a 1-tap structure, a distance to an object can be obtained by shifting phases in units of frames.

### <13. Another Example of Formation of SiGe Region>

In the configuration example of the light-receiving element 1 described above, a configuration is explained in which only a region of a part of each pixel 10 or, more specifically, the N-type semiconductor region 52 of the photodiode PD that is a photoelectric conversion region or the N-type semiconductor region 52 and a channel region below a gate of the transfer transistor TRG is made a SiGe region. In this case, as shown in FIG. 7, the SiGe region is provided separated in pixel units.

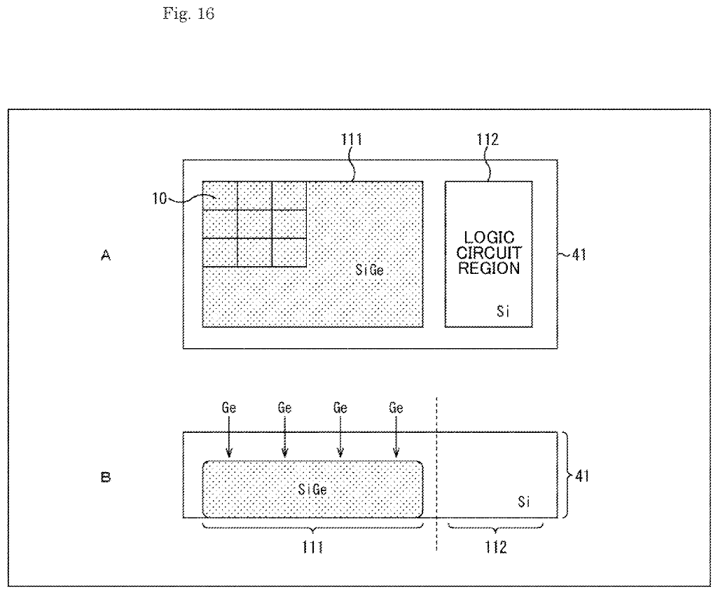

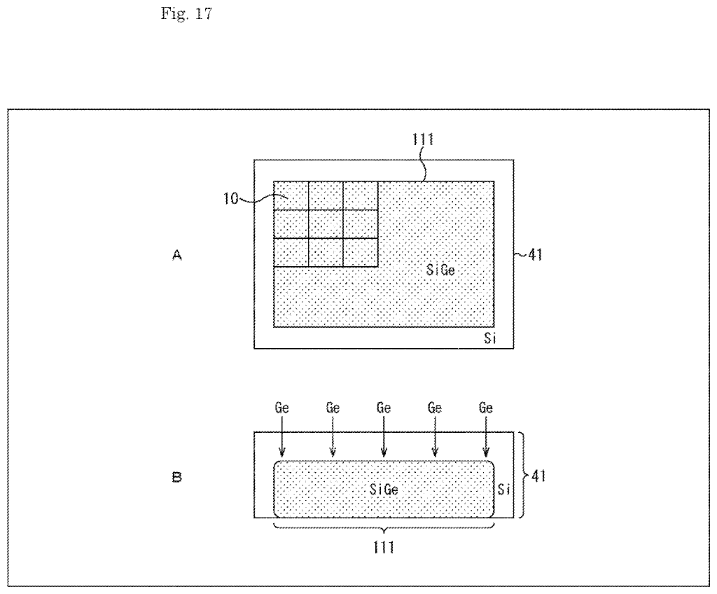

In FIGS. 16 and 17 below, a configuration in which an entirety of the pixel array region 111 (pixel array portion 21) is made a SiGe region will be described.

FIG. 16 shows a configuration example in which the entire pixel array region 111 is made a SiGe region in a case where the light-receiving element 1 is formed on a single semiconductor substrate shown in A in FIG. 12.

A in FIG. 16 is a plan view of the semiconductor substrate 41 when the pixel array region 111 and the logic circuit region 112 are formed on a same substrate. B in FIG. 16 is a sectional view of the semiconductor substrate 41.

As shown in A in FIG. 16, the entire pixel array region 111 can be made a SiGe region, in which case other regions including the logic circuit region 112 are made Si regions.

As shown in B in FIG. 16, with respect to the pixel array region 111 formed of a SiGe region, an entirety of the pixel array region 111 can be formed of a SiGe region by performing ion implantation of Ge in a portion to become the pixel array region 111 of the semiconductor substrate 41 that is an Si region.

FIG. 17 shows a configuration example in which the entire pixel array region 111 is made a SiGe region in a case where the light-receiving element 1 adopts a laminated structure of two semiconductor substrates shown in B in FIG. 12.

A in FIG. 17 is a plan view of the first substrate 41 (semiconductor substrate 41) among the two semiconductor substrates. B in FIG. 17 is a sectional view of the first substrate 41.

As shown in A in FIG. 17, the entirety of the pixel array region 111 formed on the first substrate 41 is made a SiGe region.

As shown in B in FIG. 17, with respect to the pixel array region 111 formed of a SiGe region, an entirety of the pixel array region 111 can be formed of a SiGe region by performing ion implantation of Ge in a portion to become the pixel array region 111 of the semiconductor substrate 41 that is an Si region.

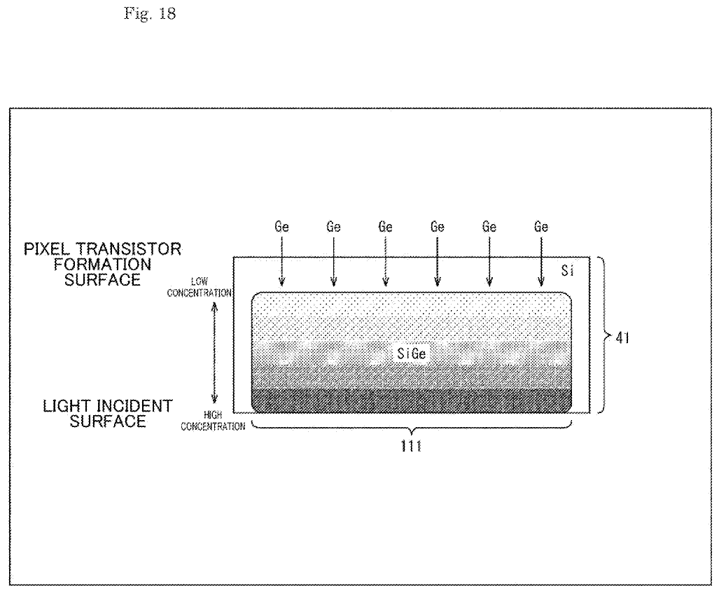

In a case where the entire pixel array region 111 is made a SiGe region, the SiGe region may be formed so that Ge concentration differs in a depth direction of the first substrate 41. Specifically, as shown in FIG. 18, the SiGe region can be formed by applying a gradient to Ge concentration depending on substrate depth so that the Ge concentration is high on a side of the light incident surface on which the on-chip lens 47 is formed, and the more toward a surface on which pixel transistors are formed, the lower the Ge concentration.

For example, a high concentration portion on the side of the light incident surface may have an Si:Ge ratio of 2:8 (Si:Ge=2:8) and a substrate concentration of 4E+22/cm3, a low concentration portion in a vicinity of the surface on which pixel transistors are formed may have an Si:Ge ratio of 8:2 (Si:Ge=8:2) and a substrate concentration of 1E+22/cm3, and the substrate concentration of the entire pixel array region 111 may range from 1E+22 to 4E+22/cm3.

Concentration can be controlled by, for example, selecting an implantation depth by controlling implantation energy during ion implantation or selecting an implantation region (region in a planar direction) using a mask. Naturally, the higher the concentration of Ge, the higher the quantum efficiency of infrared light.

### <14. Detailed Configuration Example of Pixel Area ADC>

As shown in FIGS. 16 to 18, when not only the photodiode PD (N-type semiconductor region 52) but the entirety of the pixel array region 111 is made a SiGe region, there is a concern that a dark current of the floating diffusion region FD may deteriorate. For example, as a measure against deterioration of a dark current of the floating diffusion region FD, there is a method of forming an Si layer on a SiGe region and adopting the Si layer as the floating diffusion region FD as shown in FIG. 11.

As another measure against deterioration of a dark current of the floating diffusion region FD, instead of performing AD conversion in units of columns of the pixel 10 as shown in FIG. 1, a configuration of a pixel area ADC can be adopted in which an AD converting portion is provided in pixel units or in units of n×n-number of nearby pixels (where n is an integer equal to or larger than 1). Since adopting the configuration of the pixel area ADC enables a time during which an electric charge is held by the floating diffusion region FD to be reduced as compared to the column ADC type shown in FIG. 1, a deterioration of the dark current of the floating diffusion region FD can be suppressed.

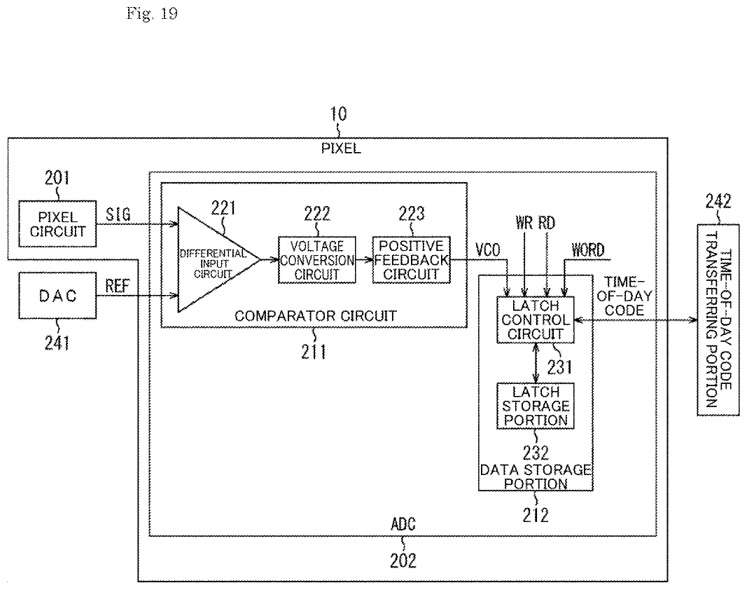

A configuration of the light-receiving element 1 in which an AD converting portion is provided in pixel units will be described with reference to FIGS. 19 to 21.

FIG. 19 is a block diagram showing a detailed configuration example of the pixel 10 including an AD converting portion per pixel.

The pixel 10 is constituted of a pixel circuit 201 and an ADC (AD converting portion) 202. When the AD converting portion is provided in units of n×n-number of pixels instead of units of pixels, one ADC 202 is provided with respect to n×n-number of pixel circuits 201.

The pixel circuit 201 outputs an electric charge signal in accordance with an amount of received light to the ADC 202 as an analog pixel signal SIG. The ADC 202 converts the analog pixel signal SIG supplied from the pixel circuit 201 into a digital signal.

The ADC 202 is constituted of a comparator circuit 211 and a data storage portion 212.

The comparator circuit 211 compares a reference signal REF supplied from a DAC 241 that is provided as a peripheral circuit portion and the pixel signal SIG from the pixel circuit 201 with each other and outputs an output signal VCO as a comparison result signal that represents a comparison result. The comparator circuit 211 inverts the output signal VCO when the reference signal REF and the pixel signal SIG are the same (voltage).

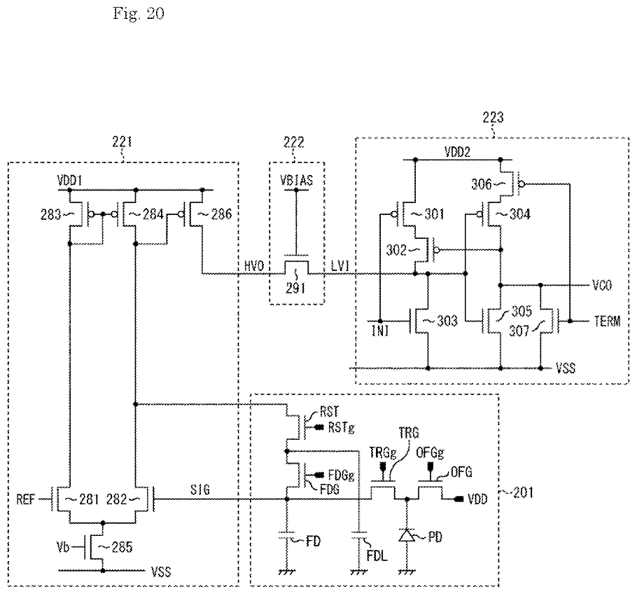

While the comparator circuit 211 is constituted of a differential input circuit 221, a voltage conversion circuit 222, and a positive feedback (PFB) circuit 223, details will be described later with reference to FIG. 20.

In addition to the output signal VCO input from the comparator circuit 211, the data storage portion 212 is supplied by the vertical driving portion 22 with a WR signal representing a write operation of a pixel signal, a RD signal representing a read operation of a pixel signal, and a WORD signal for controlling a read timing of the pixel 10 during a read operation of a pixel signal. Furthermore, a time-of-day code generated by a time-of-day code generating portion (not illustrated) in the peripheral circuit portion is supplied via a time-of-day code transferring portion 242 that is provided as a peripheral circuit portion.

The data storage portion 212 is constituted of a latch control circuit 231 that controls a write operation and a read operation of a time-of-day code based on a WR signal and an RD signal and a latch storage portion 232 that stores a time-of-day code.

During a write operation of a time-of-day code, when a Hi (High) output signal VCO is being input from the comparator circuit 211, the latch control circuit 231 causes a time-of-day code that is supplied from the time-of-day code transferring portion 242 and is updated per unit time to be stored in the latch storage portion 232. In addition, when the reference signal REF and the pixel signal SIG become the same (voltage) and the output signal VCO supplied from the comparator circuit 211 is inverted to Lo (Low), write (update) of the supplied time-of-day code is discontinued and the latch storage portion 232 is caused to hold a time-of-day code last stored in the latch storage portion 232. The time-of-day code stored in the latch storage portion 232 represents a time of day at which the pixel signal SIG and the reference signal REF had become equal to each other and represents a digitalized light amount value.

After sweeping of the reference signal REF is finished and time-of-day codes have been stored in the latch storage portions 232 of all pixels 10 in the pixel array portion 21, the operation of the pixel 10 is changed from the write operation to a read operation.

In a read operation of a time-of-day code, based on a WORD signal that controls a read timing, the latch control circuit 231 outputs a time-of-day code (a digital pixel signal SIG) stored in the latch storage portion 232 to the time-of-day code transferring portion 242 when a read timing of the pixel 10 arrives. The time-of-day code transferring portion 242 sequentially transmits the supplied time-of-day codes in a column direction (vertical direction) and supplies the time-of-day codes to the signal processing portion 26.

### <Detailed Configuration Example of Comparator Circuit>

FIG. 20 is a circuit diagram showing detailed configurations of the differential input circuit 221, the voltage conversion circuit 222, and the positive feedback circuit 223 that constitute the comparator circuit 211 and the pixel circuit 201.

Note that, due to limitations of space, FIG. 20 shows circuits corresponding to one tap among the pixel 10 constituted by two taps.

The differential input circuit 221 compares the pixel signal SIG of one of the taps output from the pixel circuit 201 in the pixel 10 and a reference signal REF output from the DAC 241 with each other and outputs a predetermined signal (current) when the pixel signal SIG is higher than the reference signal REF.

The differential input circuit 221 is constituted of transistors 281 and 282 that form a differential pair, transistors 283 and 284 that constitute a current mirror, a transistor 285 as a constant-current source that supplies a current IB in accordance with an input bias current Vb, and a transistor 286 that outputs an output signal HVO of the differential input circuit 221.

The transistors 281, 282, and 285 are constituted of an NMOS (Negative Channel MOS) transistor, and the transistors 283, 284, and 286 are constituted of a PMOS (Positive Channel MOS) transistor.

Among the transistors 281 and 282 that form a differential pair, the reference signal REF output from the DAC 241 is input to a gate of the transistor 281 and the pixel signal SIG output from the pixel circuit 201 in the pixel 10 is input to a gate of the transistor 282. Sources of the transistors 281 and 282 are connected to a drain of the transistor 285, and a source of the transistor 285 is connected to a predetermined voltage VSS (VSS<VDD2<VDD1).

A drain of the transistor 281 is connected to gates of the transistors 283 and 284 that constitute a current mirror circuit and a drain of the transistor 283, and a drain of the transistor 282 is connected to a drain of the transistor 284 and a gate of the transistor 286. Sources of the transistors 283, 284, and 286 are connected to a first power supply voltage VDD1.

The voltage conversion circuit 222 is constituted of, for example, an NMOS transistor 291. A drain of the transistor 291 is connected to a drain of the transistor 286 of the differential input circuit 221, a source of the transistor 291 is connected to a predetermined connection point in the positive feedback circuit 223, and a gate of the transistor 286 is connected to a bias voltage VBIAS.

The transistors 281 to 286 that constitute the differential input circuit 221 are circuits that operate at high voltage up to the first power supply voltage VDD1 while the positive feedback circuit 223 is a circuit that operates at a second power supply voltage VDD2 that is lower than the first power supply voltage VDD1. The voltage conversion circuit 222 converts the output signal HVO input from the differential input circuit 221 into a signal (conversion signal) LVI of a low voltage at which the positive feedback circuit 223 can operate and supplies the positive feedback circuit 223 with the signal LVI.

The bias voltage VBIAS need only be a voltage for converting to a voltage that does not destroy each of transistors 301 to 307 of the positive feedback circuit 223 that operates at a low voltage. For example, the bias voltage VBIAS can be a same voltage as the second power supply voltage VDD2 of the positive feedback circuit 223 (VBIAS=VDD2).

Based on a conversion signal LVI obtained by converting the output signal HVO from the differential input circuit 221 into a signal corresponding to the second power supply voltage VDD2, the positive feedback circuit 223 outputs a comparison result signal that is inverted when the pixel signal SIG is higher than the reference signal REF. In addition, the positive feedback circuit 223 increases a transition speed when an output signal VCO that is output as a comparison result signal is inverted.

The positive feedback circuit 223 is constituted of seven transistors 301 to 307. The transistors 301, 302, 304, and 306 are constituted of a PMOS transistor while the transistors 303, 305, and 307 are constituted of an NMOS transistor.

A source of the transistor 291 that is an output terminal of the voltage conversion circuit 222 is connected to drains of the transistors 302 and 303 and gates of the transistors 304 and 305. A source of the transistor 301 is connected to the second power supply voltage VDD2, a drain of the transistor 301 is connected to a source of the transistor 302, and a gate of the transistor 302 is connected to drains of the transistors 304 and 305 which are also output terminals of the positive feedback circuit 223. Sources of the transistors 303 and 305 are connected to a predetermined voltage VSS. An initialization signal INI is supplied to gates of the transistors 301 and 303.

The transistors 304 to 307 constitute a 2-input NOR circuit, and a connection point between drains of the transistors 304 and 305 constitute an output terminal that is used by the comparator circuit 211 to output the output signal VCO.

A control signal TERM being a second input that is not the conversion signal LVI being a first input is supplied to a gate of the transistor 306 constituted of a PMOS transistor and a gate of the transistor 307 constituted of a NMOS transistor.

A source of the transistor 306 is connected to the second power supply voltage VDD2, and a drain of the transistor 306 is connected to a source of the transistor 304. A drain of the transistor 307 is connected to an output terminal of the comparator circuit 211, and a source of the transistor 307 is connected to a predetermined voltage VSS.

An operation of the comparator circuit 211 configured as described above will be explained.

First, the reference signal REF is set to a higher voltage than the pixel signal SIG of all pixels 10 and, at the same time, the initialization signal INI is set to Hi to initialize the comparator circuit 211.

More specifically, the reference signal REF is applied to the gate of the transistor 281 and the pixel signal SIG is applied to the gate of the transistor 282. When voltage of the reference signal REF is higher than voltage of the pixel signal SIG, most of a current output by the transistor 285 that acts as a current source flows through the transistor 283 being diode-connected via the transistor 281. A channel resistance of the transistor 284 sharing a gate with the transistor 283 drops sufficiently and approximately holds the gate of the transistor 286 to a level of the first power supply voltage VDD1, and the transistor 286 is cut off. Therefore, even if the transistor 291 of the voltage conversion circuit 222 is conductive, the positive feedback circuit 223 as a charge circuit does not charge the conversion signal LVI. On the other hand, since a Hi signal is being supplied as the initialization signal INI, the transistor 303 is conductive and the positive feedback circuit 223 discharges the conversion signal LVI. In addition, since the transistor 301 is cut off, the positive feedback circuit 223 similarly does not charge the conversion signal LVI via the transistor 302. As a result, the conversion signal LVI is discharged to a level of the predetermined voltage VSS, the positive feedback circuit 223 outputs a Hi output signal VCO with the transistors 304 and 305 that constitute a NOR circuit, and the comparator circuit 211 is initialized.

After the initialization, the initialization signal INI is set to Lo and sweeping of the reference signal REF is started.

In a period where voltage of the reference signal REF is higher than that of the pixel signal SIG, since the transistor 286 is turned off and cut off while the output signal VCO is set to Hi, the transistor 302 is also turned off and cut off. The transistor 303 is also cut off since the initialization signal INI is set to Lo. The conversion signal LVI holds the predetermined voltage VSS while maintaining a high-impedance state and a Hi output signal VCO is output.

When the reference signal REF becomes lower than the pixel signal SIG, the output current of the transistor 285 being a current source ceases to flow through the transistor 281, a gate potential of the transistors 283 and 284 rises, and the channel resistance of the transistor 284 increases. In this state, a current that flows in via the transistor 282 causes a voltage drop and lowers a gate potential of the transistor 286 and the transistor 291 becomes conductive. The output signal HVO that is output from the transistor 286 is converted into the conversion signal LVI by the transistor 291 of the voltage conversion circuit 222 and supplied to the positive feedback circuit 223. The positive feedback circuit 223 as a charge circuit charges the conversion signal LVI and brings the potential close to the second power supply voltage VDD2 from the low voltage VSS.

In addition, when the voltage of the conversion signal LVI exceeds a threshold voltage of an inverter constituted by the transistors 304 and 305, the output signal VCO is set to Lo and the transistor 302 becomes conductive. The transistor 301 is also conductive due to a Lo initialization signal INI being applied thereto, and the positive feedback circuit 223 rapidly charges the conversion signal LVI via the transistors 301 and 302 and raises the potential to the second power supply voltage VDD2 at once.

Since the bias voltage VBIAS is being applied to the gate of the transistor 291 of the voltage conversion circuit 222, the transistor 291 is cut off when the voltage of the conversion signal LVI reaches a voltage value that is lower than the bias voltage VBIAS by a transistor threshold. Even if the transistor 286 remains conductive, the conversion signal LVI is not further charged and the voltage conversion circuit 222 also function as a voltage clamp circuit.

The charge of the conversion signal LVI due to conduction of the transistor 302 is, in the first place, a positive feedback operation which is triggered by a rise of the conversion signal LVI to an inverter threshold and which accelerates the rise. A current per circuit of the transistor 285 being a current source of the differential input circuit 221 is set to an extremely small current since the number of circuits that operate simultaneously in parallel in the light-receiving element 1 is enormous. In addition, since a voltage that changes in a unit time at which time-of-day codes are switched becomes an LSB step of AD conversion, the reference signal REF is swept extremely slowly. Therefore, a change in the gate potential of the transistor 286 is also slow, and a change in the output current of the transistor 286 that is driven by the gate potential is also slow. However, the output signal VCO transitions sufficiently rapidly by applying a positive feedback from a subsequent stage to the conversion signal LVI to be charged by the output current. Desirably, a transition time of the output signal VCO is a fraction of the unit time of the time-of-day code and a typical example is 1 ns or shorter. The comparator circuit 211 is capable of achieving this output transition time by simply setting a small current of, for example, 0.1 uA to the transistor 285 being a current source.

By setting a control signal TERM that is a second input of the NOR circuit to Hi, the output signal VCO can be set to Lo regardless of a state of the differential input circuit 221.

For example, when the voltage of the pixel signal SIG falls below a final voltage of the reference signal REF due to unexpectedly high brightness, a comparison period is to end with the output signal VCO of the comparator circuit 211 remaining Hi, and the data storage portion 212 controlled by the output signal VCO is unable to fix a value and an AD conversion function is lost. In order to prevent an occurrence of such a situation, by inputting the control signal TERM of a Hi pulse after the end of sweeping of the reference signal REF, the output signal VCO that is not yet inverted to Lo can be forcibly inverted. Since the data storage portion 212 stores (latches) a time-of-day code immediately preceding a forcible inversion, when the configuration shown in FIG. 20 is adopted, the ADC 202 consequently functions as an AD converter that clamps an output value with respect to an input of brightness of a certain level or higher.

When the bias voltage VBIAS is controlled to a Lo level, the transistor 291 is cut off, and the initialization signal INI is set to Hi, the output signal VCO changes to Hi regardless of the state of the differential input circuit 221. Therefore, by combining the forcible Hi output of the output signal VCO and the forcible Lo output by the control signal TERM described above, the output signal VCO can be set to an arbitrary value regardless of the state of the differential input circuit 221 and states of the pixel circuit 201 and the DAC 241 which constitute a preceding stage thereof. According to this function, for example, circuits in a subsequent stage to the pixel 10 can be tested using only an electric signal input without depending on an optical input to the light-receiving element 1.

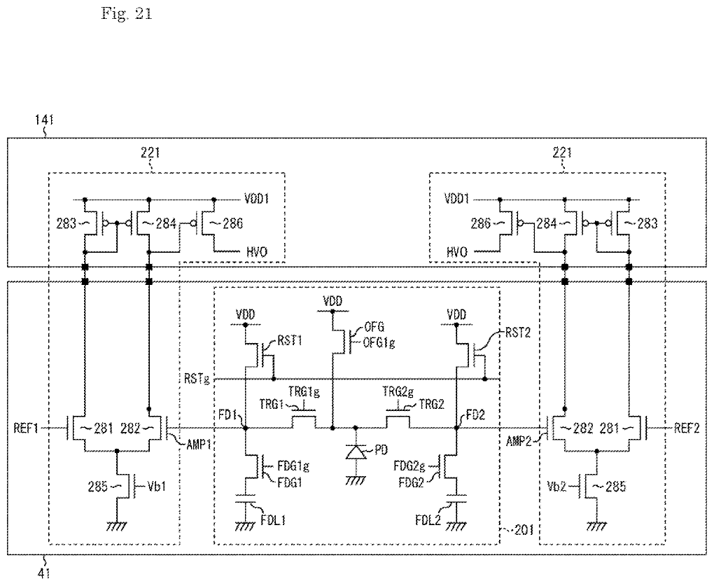

FIG. 21 is a circuit diagram showing a connection between an output of each tap of the pixel circuit 201 and the differential input circuit 221 of the comparator circuit 211.

As shown in FIG. 21, the differential input circuit 221 of the comparator circuit 211 shown in FIG. 20 is connected to an output destination of each tap of the pixel circuit 201.

The pixel circuit 201 shown in FIG. 20 is equivalent to the pixel circuit 201 shown in FIG. 21 and is similar to the circuit configuration of the pixel 10 shown in FIG. 3.

When adopting a configuration of the pixel area ADC, since the number of circuits in pixel units or in units of n×n-number of pixels (where n is an integer equal to or larger than 1) increases, the light-receiving element 1 is constituted of the laminated structure shown in B in FIG. 12. In this case, for example, as shown in FIG. 21, circuits up to the pixel circuit 201 and the transistors 281, 282, and 285 of the differential input circuit 221 can be arranged on the first substrate 41 and other circuits can be arranged on the second substrate 141. The first substrate 41 and the second substrate 141 are electrically connected to each other by a Cu—Cu bond. Note that a circuit arrangement of the first substrate 41 and the second substrate 141 is not limited to this example.

As described above, by adopting a configuration of the pixel area ADC as a measure against deterioration of a dark current of the floating diffusion region FD when the entirety of the pixel array region 111 is made a SiGe region, since a time during which an electric charge is accumulated in the floating diffusion region FD can be reduced as compared to the column ADC shown in FIG. 1, a deterioration of the dark current of the floating diffusion region FD can be suppressed.

### <15. Sectional View According to Second Configuration Example of Pixel>

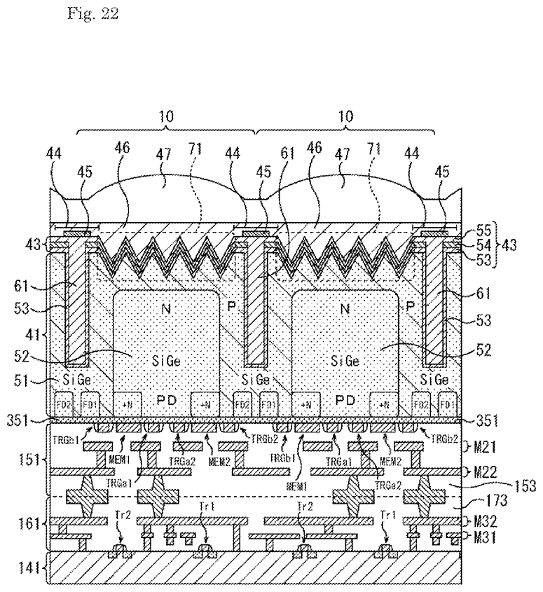

FIG. 22 is a sectional view showing a second configuration example of the pixels 10 arranged in the pixel array portion 21.

In FIG. 22, portions corresponding to those in the first configuration example shown in FIG. 2 are denoted by the same reference signs and descriptions of the portions will be appropriately omitted.

FIG. 22 is a sectional view of a pixel structure of the memory MEM-holding pixel 10 shown in FIG. 5 and represents a sectional view in a case where the pixel 10 is constituted of the laminated structure of two substrates shown in B in FIG. 12.

However, compared to the metal film M of the wiring layer 151 on the side of the first substrate 41 and the metal film M of the wiring layer 161 of the second substrate 141 being electrically connected to each other by the TSV 171 and the TSV 172 in the sectional view of the laminated structure shown in FIG. 13, the electrical connection is realized by a Cu—Cu bond in FIG. 22.

Specifically, the wiring layer 151 of the first substrate 41 includes a first metal film M21, a second metal film M22, and the insulating layer 153, and the wiring layer 161 of the second substrate 141 includes a first metal film M31, a second metal film M32, and the insulating layer 173. The wiring layer 151 of the first substrate 41 and the wiring layer 161 of the second substrate 141 are electrically connected to each other by Cu films formed in a part of a bonding surface indicated by a dashed line.

In the second configuration example shown in FIG. 22, an entirety of the pixel array region 111 of the first substrate 41 explained with reference to FIG. 17 is made a SiGe region. In other words, the P-type semiconductor region 51 and the N-type semiconductor region 52 are formed of SiGe regions. Accordingly, quantum efficiency with respect to infrared light is improved.

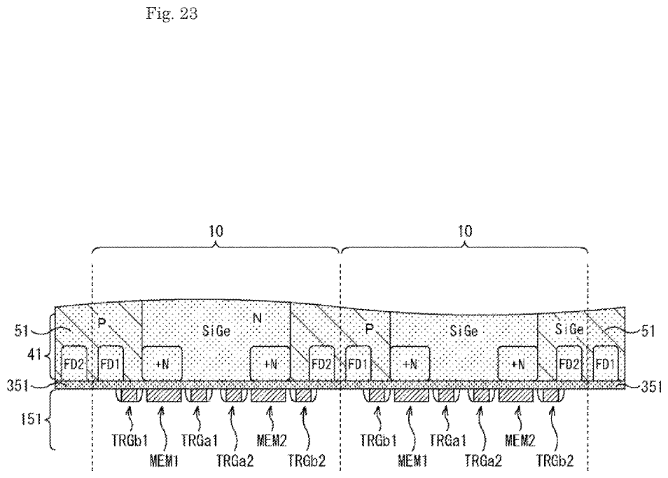

A pixel transistor formation surface of the first substrate 41 will now be described with reference to FIG. 23.

FIG. 23 is an enlarged sectional view of a vicinity of pixel transistors of the first substrate 41 shown in FIG. 22.

First transfer transistors TRGa1 and TRGa2, second transfer transistors TRGb1 and TRGb2, and memories MEM1 and MEM2 are formed on an interface on a side of the wiring layer 151 of the first substrate 41 for each pixel 10.

An oxide film 351 is formed with a film thickness of, for example, around 10 to 100 nm on the interface on a side of the wiring layer 151 of the first substrate 41. The oxide film 351 is formed by forming a silicon film on a surface of the first substrate 41 by epitaxial growth and by heat-treating the silicon film. The oxide film 351 also functions as respective gate insulating films of the first transfer transistor TRGa and the second transfer transistor TRGb.

Since it is difficult to form a high-quality oxide film in a SiGe region as compared to an Si region, a dark current generated from the transfer transistor TRG or the memory MEM increases. In particular, in the light-receiving element 1 adopting an indirect ToF system, since an operation of alternately turning the transfer transistor TRG on and off between two or more taps is repetitively performed, a dark current attributable to a gate that is generated when the transfer transistor TRG is turned on cannot be ignored.

A dark current attributable to an interface state can be reduced by the oxide film 351 with a film thickness of around 10 to 100 nm. Therefore, according to the second configuration example, a dark current can be suppressed while increasing quantum efficiency. A similar advantageous effect can be produced even when a Ge region is formed in place of a SiGe region.

When the pixel 10 does not have a laminated structure of two substrates and all pixel transistors are formed on a surface on one side of a single semiconductor substrate 41 as shown in FIG. 2, a reset noise from the amplifying transistor AMP can also be reduced by forming the oxide film 351.

### <16. Sectional View According to Third Configuration Example of Pixel>

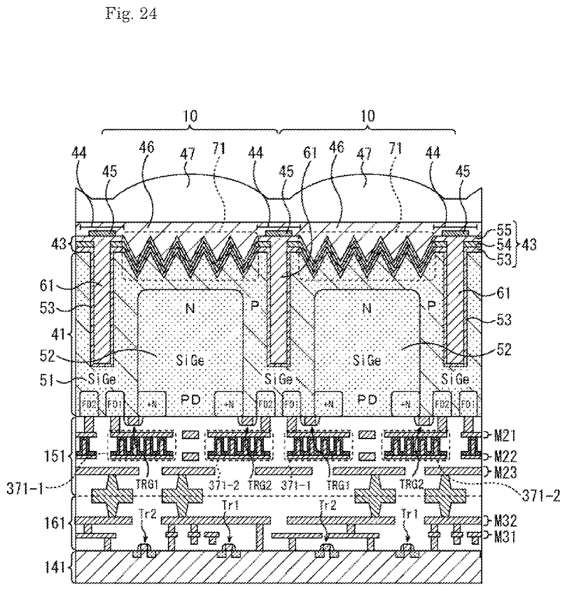

FIG. 24 is a sectional view showing a third configuration example of the pixels 10 arranged in the pixel array portion 21.

Portions corresponding to those in the first configuration example shown in FIG. 2 and the second configuration example shown in FIG. 22 are denoted by the same reference signs and descriptions of the portions will be appropriately omitted.

FIG. 24 is a sectional view of the pixel 10 when the light-receiving element 1 is constituted of a laminated structure of two substrates and when connection is provided by a Cu—Cu bond in a similar manner to the second configuration example shown in FIG. 22. In addition, in a similar manner to the second configuration example shown in FIG. 22, the entirety of the pixel array region 111 of the first substrate 41 is formed of a SiGe region.

When the floating diffusion regions FD1 and FD2 are formed of a SiGe region, there is a problem in that a dark current generated from the floating diffusion regions FD increases as described above. Therefore, in order to minimize the effect of the dark current, the floating diffusion regions FD1 and FD2 formed in the first substrate 41 are formed with small volumes.

However, simply reducing the volumes of the floating diffusion regions FD1 and FD2 results in reducing capacitances of the floating diffusion regions FD1 and FD2 and prevents a sufficient electric charge from accumulating.

In consideration thereof, in the third configuration example shown in FIG. 24, a capacitance of the floating diffusion region FD is increased by forming an MIM (Metal Insulator Metal) capacitative element 371 on the wiring layer 151 of the first substrate 41 and constantly connecting the MIM capacitative element 371 to the floating diffusion region FD. Specifically, an MIM capacitative element 371-1 is connected to the floating diffusion region FD1 and an MIM capacitative element 371-2 is connected to the floating diffusion region FD2. The MIM capacitative element 371 realizes a small mounting area by adopting a U-shaped three-dimensional structure.

With the pixel 10 according to the third configuration example shown in FIG. 24, insufficient capacitance of the floating diffusion region FD having been formed with a small volume in order to suppress generation of a dark current can be compensated for by the MIM capacitative element 371. Accordingly, both suppression of a dark current and securement of capacitance when using a SiGe region can be realized at the same time. In other words, according to the third configuration example, a dark current can be suppressed while increasing quantum efficiency with respect to infrared light.

While an MIM capacitative element has been described as an additional capacitative element to be connected to the floating diffusion region FD in the example shown in FIG. 24, the additional capacitative element is not limited to an MIM capacitative element. For example, the additional capacitor may be a MOM (Metal Oxide Metal) capacitative element, a Poly-Poly capacitative element (a capacitative element in which both opposing electrodes are formed of polysilicon), a capacitative element formed of wiring, or the like.

In addition, when the pixel 10 adopts a pixel structure including memories MEM1 and MEM2 as in the case of the second configuration example shown in FIG. 22, a configuration can be adopted in which an additional capacitative element is not only connected to the floating diffusion region FD but also connected to the memories MEM.

Although the additional capacitative element to be connected to the floating diffusion region FD or the memory MEM is formed on the wiring layer 151 of the first substrate 41 in the example shown in FIG. 24, alternatively, the additional capacitative element may be formed on the wiring layer 161 of the second substrate 14.

While the light-shielding member 63 and the wiring capacitance 64 in the first configuration example shown in FIG. 2 are omitted in the example shown in FIG. 24, the light-shielding member 63 and the wiring capacitance 64 may be formed.

### <17. Configuration Example of IR Imaging Sensor>

The structure of the light-receiving element 1 in which quantum efficiency of near-infrared light has been improved due to making the photodiode PD or the pixel array region 111 a SiGe region or a Ge region can be adopted by not only an indirect ToF system ranging sensor that outputs ranging information but also other sensors that receive infrared light.

Hereinafter, as examples of another sensor in which a part of a semiconductor substrate is made a SiGe region or a Ge region, examples of an IR imaging sensor that receives infrared light and generates an IR image and an RGBIR imaging sensor that receives infrared light and RGB light will be described.

In addition, as other examples of a ranging sensor that receives infrared light and outputs ranging information, examples of a direct ToF system ranging sensor using an SPAD pixel and a ToF sensor adopting a CAPD (Current Assisted Photonic Demodulator) system will be described.

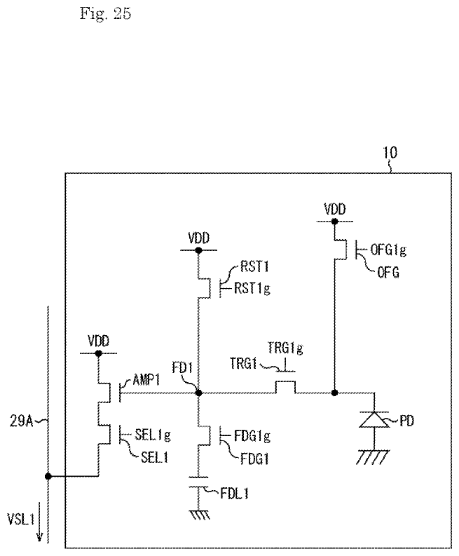

FIG. 25 shows a circuit configuration of the pixel 10 in a case where the light-receiving element 1 is configured as an IR imaging sensor that generates and outputs an IR image.

In a case where the light-receiving element 1 is a ToF sensor, in order to distribute an electric charge generated by the photodiode PD into two floating diffusion regions FD1 and FD2 and accumulate the electric charge, the pixel 10 includes two each of the transfer transistor TRG, the floating diffusion region FD, the additional capacitor FDL, the switching transistor FDG, the amplifying transistor AMP, the reset transistor RST, and the selective transistor SEL.

In a case where the light-receiving element 1 is an IR imaging sensor, since only one electric charge holding portion is necessary for temporarily holding an electric charge generated by the photodiode PD, one each of the transfer transistor TRG, the floating diffusion region FD, the additional capacitor FDL, the switching transistor FDG, the amplifying transistor AMP, the reset transistor RST, and the selective transistor SEL are similarly necessary.

In other words, in a case where the light-receiving element 1 is an IR imaging sensor, as shown in FIG. 25, the pixel 10 is equivalent to a configuration as a result of omitting the transfer transistor TRG2, the switching transistor FDG2, the reset transistor RST2, the amplifying transistor AMP2, and the selective transistor SEL2 from the circuit configuration shown in FIG. 3. The floating diffusion region FD2 and the vertical signal line 29B are also omitted.

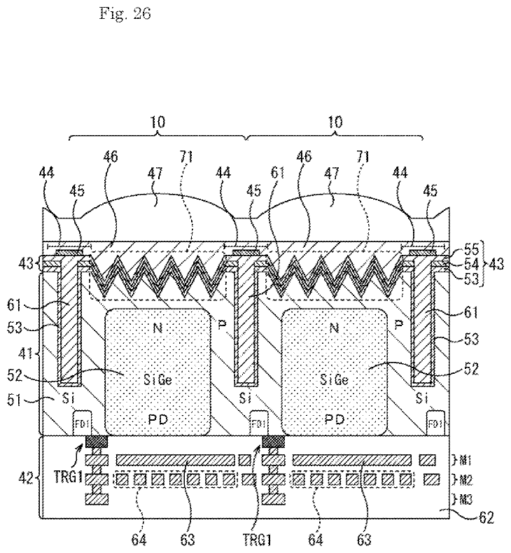

FIG. 26 is a sectional view showing a configuration example of the pixel 10 in a case where the light-receiving element 1 is configured as an IR imaging sensor.

A difference between a case where the light-receiving element 1 is configured as an IR imaging sensor and a case where the light-receiving element 1 is configured as a ToF sensor is, as described in FIG. 25, the presence or absence of the floating diffusion region FD2 formed on the front surface side of the semiconductor substrate 41 and the pixel transistors. For this reason, a configuration of the multilayer wiring layer 42 formed on the front surface side of the semiconductor substrate 41 differs from that in FIG. 2. In addition, the floating diffusion region FD2 is omitted. Other components in FIG. 26 are similar to those shown in FIG. 2.

Even in FIG. 26, quantum efficiency of near-infrared light can be improved by making the photodiode PD a SiGe region or a Ge region. Not only the first configuration example shown in FIG. 2 described above but also the configuration of the pixel area ADC, the second configuration example shown in FIG. 22, and the third configuration example shown in FIG. 24 can be applied to an IR imaging sensor in a similar manner. In addition, as described with reference to FIGS. 16 to 18, not only the photodiode PD but also the entire pixel array region 111 may be made a SiGe region or a Ge region.

### <18. Configuration Example of RGBIR Imaging Sensor>

While all of the pixels 10 in the light-receiving element 1 having the pixel structure shown in FIG. 26 are sensors that receive infrared light, the light-receiving element 1 can also be applied to an RGBIR imaging sensor that receives infrared light and RGB light.

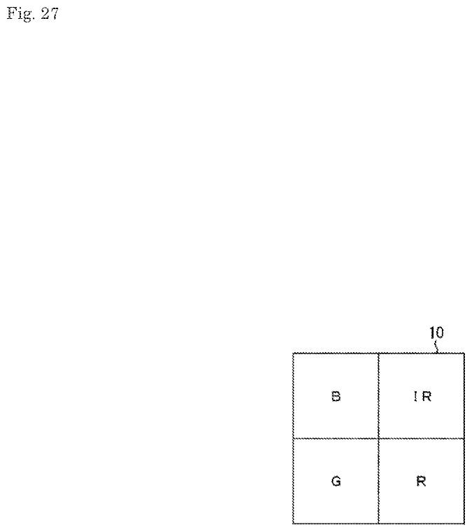

When the light-receiving element 1 is configured as an RGBIR imaging sensor that receives infrared light and RGB light, for example, a 2×2 pixel arrangement shown in FIG. 27 is repetitively arrayed in the row direction and the column direction.

FIG. 27 shows an arrangement example of pixels in a case where the light-receiving element 1 is configured as an RGBIR imaging sensor that receives infrared light and RGB light.

When the light-receiving element 1 is configured as an RGBIR imaging sensor, an R pixel that receives light of R (red), a B pixel that receives light of B (blue), a G pixel that receives light of G (green), and an IR pixel that receives light of IR (infrared) are allocated to 2×2=4 pixels as shown in FIG. 27.

In an RGBIR imaging sensor, which of an R pixel, a B pixel, a G pixel, and an IR pixel each pixel 10 will be is determined by a color filter layer that is inserted between the planarizing film 46 and the on-chip lens 47 shown in FIG. 26.

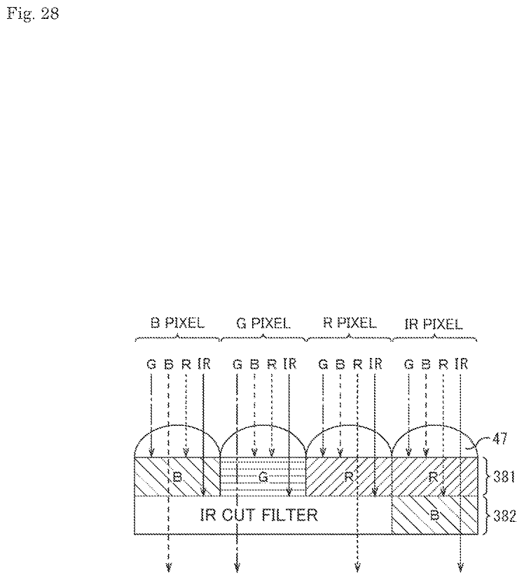

FIG. 28 is a sectional view showing an example of the color filter layer that is inserted between the planarizing film 46 and the on-chip lens 47 when the light-receiving element 1 is configured as an RGBIR imaging sensor.

In FIG. 28, a B pixel, a G pixel, an R pixel, and an IR pixel are arranged in this order from left to right.

A first color filter layer 381 and a second color filter layer 382 are inserted between the planarizing film 46 (not illustrated in FIG. 28) and the on-chip lens 47.

In the B pixel, a B filter that transmits B light is arranged on the first color filter layer 381 and an IR cut filter that cuts off IR light is arranged on the second color filter layer 382. Accordingly, only B light passes through the first color filter layer 381 and the second color filter layer 382 and is incident to the photodiode PD.

In the G pixel, a G filter that transmits G light is arranged on the first color filter layer 381 and an IR cut filter that cuts off IR light is arranged on the second color filter layer 382. Accordingly, only G light passes through the first color filter layer 381 and the second color filter layer 382 and is incident to the photodiode PD.

In the R pixel, an R filter that transmits R light is arranged on the first color filter layer 381 and an IR cut filter that cuts off IR light is arranged on the second color filter layer 382. Accordingly, only R light passes through the first color filter layer 381 and the second color filter layer 382 and is incident to the photodiode PD.

In the IR pixel, an R filter that transmits R light is arranged on the first color filter layer 381 and a B filter that transmits B light is arranged on the second color filter layer 382. Accordingly, since light with a wavelength other than from B to R is transmitted, IR light passes through the first color filter layer 381 and the second color filter layer 382 and is incident to the photodiode PD.

When the light-receiving element 1 is configured as an RGBIR imaging sensor, the photodiode PD of the IR pixel is formed of the SiGe region or the Ge region described above and photodiodes PD of the R pixel, the G pixel, and the R pixel are formed of Si regions.

Even when the light-receiving element 1 is configured as an RGBIR imaging sensor, quantum efficiency of near-infrared light can be improved by making the photodiode PD of the IR pixel a SiGe region or a Ge region. Not only the first configuration example shown in FIG. 2 described above but also the configuration of the pixel area ADC, the second configuration example shown in FIG. 22, and the third configuration example shown in FIG. 24 can be applied to the RGBIR imaging sensor in a similar manner. In addition, as described with reference to FIGS. 16 to 18, not only the photodiode PD but also the entire pixel array region 111 may be made a SiGe region or a Ge region.

### <19. Configuration Example of SPAD Pixel>

Next, an example in which the structure of the pixel 10 described above is applied to a direct ToF system ranging sensor using a SPAD pixel will be described.

ToF sensors include a direct ToF sensor and an indirect ToF sensor. While an indirect ToF sensor employs a system which detects a time of flight from emission of irradiating light to reception of reflected light as a phase difference to calculate a distance to an object, a direct ToF sensor employs a system which directly measures a time of flight from emission of irradiating light to reception of reflected light to calculate a distance to an object.

In the light-receiving element 1 that directly measures a time of flight, for example, a SPAD (Single Photon Avalanche Diode) or the like is used as a photoelectric conversion element of each pixel 10.

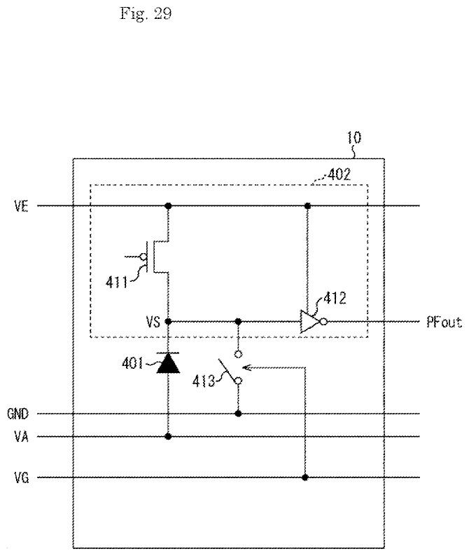

FIG. 29 shows a circuit configuration example of a SPAD pixel that uses a SPAD as the photoelectric conversion element of the pixel 10.

The pixel 10 shown in FIG. 29 includes a SPAD 401 and a readout circuit 402 constituted of a transistor 411 and an inverter 412. In addition, the pixel 10 also includes a switch 413. The transistor 411 is constituted by a P-type MOS transistor.

A cathode of the SPAD 401 is connected to a drain of the transistor 411 and, at the same time, connected to an input terminal of the inverter 412 and to one end of the switch 413. An anode of the SPAD 401 is connected to a power supply voltage VA (hereinafter, also referred to as an anode voltage VA).

The SPAD 401 is a photodiode (a single-photon avalanche photodiode) which, when incident light is incident, subjects generated electrons to avalanche amplification and outputs a signal of a cathode voltage VS. The power supply voltage VA that is supplied to the anode of the SPAD 401 is, for example, a negative bias (negative potential) of around −20 V.

The transistor 411 is a constant-current source that operates in a saturated region and performs a passive quench by acting as a quenching resistor. A source of the transistor 411 is connected to the power supply voltage VE, and a drain of the transistor 411 is connected to the cathode of the SPAD 401, the input terminal of the inverter 412, and one end of the switch 413. Accordingly, the power supply voltage VE is also supplied to the cathode of the SPAD 401. A pull-up resistor can also be used in place of the transistor 411 that is connected in series to the SPAD 401.

In order to detect light (photons) with sufficient efficiency, a voltage (excess bias) that is larger than a breakdown voltage VBD of the SPAD 401 is applied to the SPAD 401. For example, when the breakdown voltage VBD of the SPAD 401 is 20 V and a voltage larger by 3 V is to be applied, the power supply voltage VE to be supplied to the source of the transistor 411 is 3 V.

The breakdown voltage VBD of the SPAD 401 varies significantly depending on temperature or the like. Therefore, applied voltage to be applied to the SPAD 401 is controlled (adjusted) in accordance with a change in the breakdown voltage VBD. For example, when the power supply voltage VE is a fixed voltage, the anode voltage VA is controlled (adjusted).

Of two ends of the switch 413, one end is connected to the cathode of the SPAD 401, the input terminal of the inverter 412, and the drain of the transistor 411 while another end is connected to ground (GND). The switch 413 can be constituted of, for example, an N-type MOS transistor and is turned on or off in accordance with a gating control signal VG that is supplied from the vertical driving portion 22.

The vertical driving portion 22 supplies a High or Low gating control signal VG to the switch 413 of each pixel 10 and, by turning the switch 413 on or off, sets each pixel 10 of the pixel array portion 21 as an active pixel or an inactive pixel. An active pixel is a pixel that detects an incidence of a photon and an inactive pixel is a pixel that does not detect an incidence of a photon. When the switch 413 is turned on according to the gating control signal VG and the cathode of the SPAD 401 is controlled to ground, the pixel 10 becomes an inactive pixel.

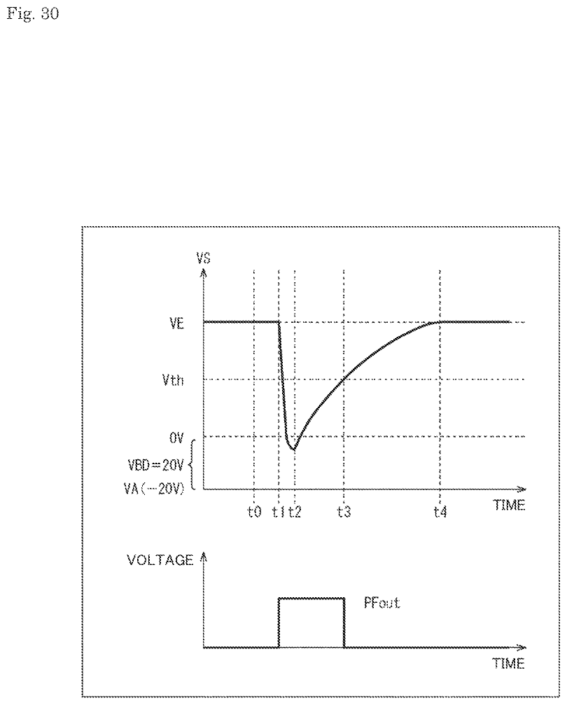

An operation in a case where the pixel 10 shown in FIG. 29 is set as an active pixel will be described with reference to FIG. 30.

FIG. 30 is a graph showing a change in the cathode voltage VS of the SPAD 401 and a pixel signal PFout in accordance with an incidence of a photon.

First, when the pixel 10 is an active pixel, the switch 413 is set to an off state as described above.

Since the power supply voltage VE (for example, 3 V) is supplied to the cathode of the SPAD 401 and the power supply voltage VA (for example, −20 V) is supplied to the anode of the SPAD 401, due to an inverse voltage larger than the breakdown voltage VBD (=20 V) being applied to the SPAD 401, the SPAD 401 is set to a Geiger mode. In this state, the cathode voltage VS of the SPAD 401 is the same as the power supply voltage VE as at a time of day t0 in FIG. 30.

When a photon is incident to the SPAD 401 being set to the Geiger mode, an avalanche multiplication occurs and a current flows through the SPAD 401.

Assuming that an avalanche multiplication has occurred and a current has flowed through the SPAD 401 at a time of day t1 in FIG. 30, after the time of day t1, the current flowing through the SPAD 401 causes a current to flow through the transistor 411 and a voltage drop occurs due to a resistance component of the transistor 411.

At a time of day t2, when the cathode voltage VS of the SPAD 401 falls below 0 V, since a state is created where an anode-cathode voltage of the SPAD 401 is lower than the breakdown voltage VBD, the avalanche multiplication stops. In this case, a quench operation refers to an operation in which a current generated by avalanche multiplication flows through the transistor 411 and causes a voltage drop and, due to the occurrence of the voltage drop, a state where the cathode voltage VS is lower than the breakdown voltage VBD is created to stop the avalanche multiplication.

When the avalanche multiplication stops, the current flowing through a resistor of the transistor 411 gradually decreases and, at a time of day t4, the cathode voltage VS once again returns to the original power supply voltage VE and a state is created where a next new photon can be detected (recharge operation).

When the cathode voltage VS being an input voltage is equal to or higher than a predetermined threshold voltage Vth, the inverter 412 outputs a Lo pixel signal PFout, but when the cathode voltage VS is lower than the predetermined threshold voltage Vth, the inverter 412 outputs a Hi pixel signal PFout. Therefore, when a photon is incident to the SPAD 401, an avalanche multiplication occurs, and a cathode voltage VS drops and falls below the threshold voltage Vth, the pixel signal PFout is inverted from a low level to a high level. On the other hand, when the avalanche multiplication of the SPAD 401 converges and the cathode voltage VS rises and equals or exceeds the threshold voltage Vth, the pixel signal PFout is inverted from a high level to a low level.

When the pixel 10 is an inactive pixel, the switch 413 is turned on. When the switch 413 is turned on, the cathode voltage VS of the SPAD 401 becomes 0 V. As a result, since the anode-cathode voltage of the SPAD 401 equals or falls below the breakdown voltage VBD, a state is created where, even if a photo is incident to the SPAD 401, there is no response.

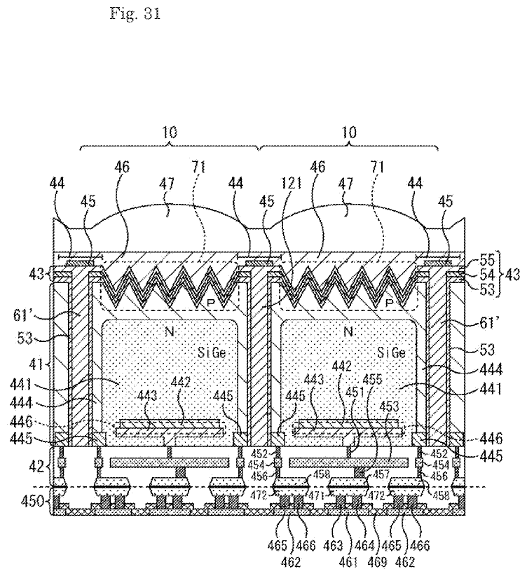

FIG. 31 is a sectional view showing a configuration example in a case where the pixel 10 is a SPAD pixel.

In FIG. 31, portions corresponding to those in the other configuration examples described above are denoted by the same reference signs and descriptions of the portions will be appropriately omitted.

In FIG. 31, the inter-pixel separation portion 61 formed until reaching a predetermined depth from a rear surface side (the side of the on-chip lens 47) of the semiconductor substrate 41 in a substrate depth direction in the pixel boundary portion 44 shown in FIG. 2 has been changed to an inter-pixel separation portion 61′ that penetrates the semiconductor substrate 41.

A pixel region on an inner side of the inter-pixel separation portion 61′ of the semiconductor substrate 41 includes an N well region 441, a P-type diffusion layer 442, an N-type diffusion layer 443, a hole accumulation layer 444, and a high-concentration P-type diffusion layer 445. In addition, an avalanche multiplication region 446 is formed by a depletion layer that is formed in a region where the P-type diffusion layer 442 and the N-type diffusion layer 443 connect to each other.

The N well region 441 is formed when an impurity concentration of the semiconductor substrate 41 is controlled to an N-type and constitutes an electric field that transfers electrons generated by photoelectric conversion in the pixel 10 to the avalanche multiplication region 446. The N well region 441 is formed of a SiGe region or a Ge region.

The P-type diffusion layer 442 is a high-concentration P-type diffusion layer (P+) that is formed over almost the entire pixel region in a planar direction. The N-type diffusion layer 443 is a high-concentration N-type diffusion layer (N+) that is formed in a vicinity of the surface of the semiconductor substrate 41 over almost the entire pixel region in a similar manner to the P-type diffusion layer 442. The N-type diffusion layer 443 is a contact layer that is connected to a contact electrode 451 as a cathode electrode for suppling a negative voltage for forming the avalanche multiplication region 446, and a part of the N-type diffusion layer 443 has a convex shape that is formed until the contact electrode 451 on the surface of the semiconductor substrate 41. The power supply voltage VE is applied to the N-type diffusion layer 443 from the contact electrode 451.

The hole accumulation layer 444 is a P-type diffusion layer (P) that is formed so as to surround a side surface and a bottom surface of the N well region 441 and holes are accumulated therein. In addition, the hole accumulation layer 444 is connected to the high-concentration P-type diffusion layer 445 to be electrically connected to a contact electrode 452 as an anode electrode of the SPAD 401.

The high-concentration P-type diffusion layer 445 is a high-concentration P-type diffusion layer (P++) that is formed in a vicinity of the surface of the semiconductor substrate 41 so as to surround an outer periphery of the N well region 441 in the planar direction and constitutes a contact layer for electrically connecting the hole accumulation layer 444 and the contact electrode 452 of the SPAD 401 to each other. The power supply voltage VA is applied to the high-concentration P-type diffusion layer 445 from the contact electrode 452.

Note that a P well region in which the impurity concentration of the semiconductor substrate 41 is controlled to a P-type may be formed in place of the N well region 441. When a P well region is formed in place of the N well region 441, the voltage applied to the N-type diffusion layer 443 is the power supply voltage VA and the voltage applied to the high-concentration P-type diffusion layer 445 is the power supply voltage VE.

The contact electrodes 451 and 452, metal wirings 453 and 454, contact electrodes 455 and 456, and metal pads 457 and 458 are formed on the multilayer wiring layer 42.

In addition, the multilayer wiring layer 42 is bonded to a wiring layer 450 (hereinafter, referred to as a logic wiring layer 450) of a logic circuit substrate on which a logic circuit is formed. The readout circuit 402 described above, a MOS transistor as the switch 413, and the like are formed on the logic circuit substrate.

The contact electrode 451 connects the N-type diffusion layer 443 and the metal wiring 453 to each other and the contact electrode 452 connects the high-concentration P-type diffusion layer 445 and the metal wiring 454 to each other.

As shown in FIG. 31, the metal wiring 453 is formed wider than the avalanche multiplication region 446 so as to cover at least the avalanche multiplication region 446 in a plan view. In addition, the metal wiring 453 reflects, toward the semiconductor substrate 41, light transmitted through the semiconductor substrate 41.

As shown in FIG. 31, the metal wiring 454 is formed in an outer periphery of the metal wiring 453 so as to overlap with the high-concentration P-type diffusion layer 445 in a plan view.

The contact electrode 455 connects the metal wiring 453 and the metal pad 457 to each other and the contact electrode 456 connects the metal wiring 454 and the metal pad 458 to each other.

The metal pads 457 and 458 are electrically and mechanically connected to metal pads 471 and 472 formed on the logic wiring layer 450 by metal-to-metal bonding of a metal (Cu) that forms each of the metal pads.

Electrode pads 461 and 462, contact electrodes 463 to 466, an insulating layer 469, and metal pads 471 and 472 are formed on the logic wiring layer 450.

Each of the electrode pads 461 and 462 is used for a connection with a logic circuit substrate (not illustrated) and the insulating layer 469 insulates the electrode pads 461 and 462 from each other.

The contact electrodes 463 and 464 connect the electrode pad 461 and the metal pad 471 to each other, and the contact electrodes 465 and 466 connect the electrode pad 462 and the metal pad 472 to each other.

The metal pad 471 is bonded to the metal pad 457, and the metal pad 472 is bonded to the metal pad 458.

Due to such a wiring structure, for example, the electrode pad 461 is connected to the N-type diffusion layer 443 via the contact electrodes 463 and 464, the metal pad 471, the metal pad 457, the contact electrode 455, the metal wiring 453, and the contact electrode 451. Therefore, in the pixel 10 shown in FIG. 31, the power supply voltage VE applied to the N-type diffusion layer 443 can be supplied from the electrode pad 461 of the logic circuit board.

In addition, the electrode pad 462 is connected to the high-concentration P-type diffusion layer 445 via the contact electrodes 465 and 466, the metal pad 472, the metal pad 458, the contact electrode 456, the metal wiring 454, and the contact electrode 452. Therefore, in the pixel 10 shown in FIG. 31, the anode voltage VA applied to the hole accumulation layer 444 can be supplied from the electrode pad 462 of the logic circuit board.

Even in the pixel 10 as a SPAD pixel configured as described above, by forming at least the N well region 441 of a SiGe region or a Ge region, quantum efficiency of infrared light can be improved and sensor sensitivity can be increased. In addition to the N well region 441, the hole accumulation layer 444 may also be formed of a SiGe region or a Ge region.

### <20. Configuration Example of CAPD Pixel>

Next, an example of applying the structure of the light-receiving element 1 described above to a ToF sensor adopting a CAPD system will be described.

The pixel 10 described with reference to FIGS. 2, 3, and the like adopts a configuration of a ToF sensor that is referred to as a gate system in which an electric charge generated by the photodiode PD is distributed by two gates (transfer transistors TRG).

By comparison, there are ToF sensors referred to as a CAPD system in which a voltage is directly applied to the semiconductor substrate 41 of a ToF sensor to generate a current inside the substrate, and a photoelectric conversion region that covers a wide range in the substrate is modulated at high speed to distribute a photoelectrically converted electric charge.

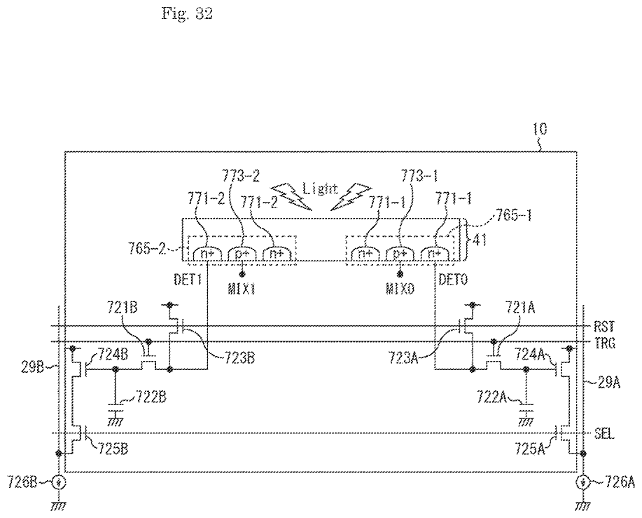

FIG. 32 shows a circuit configuration example in a case where the pixel 10 is a CAPD pixel adopting the CAPD system.

The pixel 10 shown in FIG. 32 includes signal extracting portions 765-1 and 765-2 inside the semiconductor substrate 41. The signal extracting portion 765-1 includes at least an N+ semiconductor region 771-1 that is an N-type semiconductor region and a P+ semiconductor region 773-1 that is a P-type semiconductor region. The signal extracting portion 765-2 includes at least an N+ semiconductor region 771-2 that is an N-type semiconductor region and a P+ semiconductor region 773-2 that is a P-type semiconductor region.

With respect to the signal extracting portion 765-1, the pixel 10 includes a transfer transistor 721A, an FD 722A, a reset transistor 723A, an amplifying transistor 724A, and a selective transistor 725A.

In addition, with respect to the signal extracting portion 765-2, the pixel 10 includes a transfer transistor 721B, an FD 722B, a reset transistor 723B, an amplifying transistor 724B, and a selective transistor 725B.

The vertical driving portion 22 applies a predetermined voltage MIX0 (first voltage) to the P+ semiconductor region 773-1 and applies a predetermined voltage MIX1 (second voltage) to the P+ semiconductor region 773-2. For example, one of the voltages MIX0 and MIX1 is set to 1.5 V and the other is set to 0 V. The P+ semiconductor regions 773-1 and 773-2 are voltage applying portions where the first voltage or the second voltage is applied.

The N+ semiconductor regions 771-1 and 771-2 are electric charge detection portions which detect electric charges generated by photoelectrically converting light incident to the semiconductor substrate 41 and which accumulate the electric charges.

The transfer transistor 721A changes to a conductive state in response to a change of a transfer drive signal TRG supplied to a gate electrode into an active state to transfer an electric charge accumulated in the N+ semiconductor region 771-1 to the FD 722A. The transfer transistor 721B changes to a conductive state in response to a change of a transfer drive signal TRG supplied to a gate electrode into an active state to transfer an electric charge accumulated in the N+ semiconductor region 771-2 to the FD 722B.

The FD 722A temporarily holds the electric charge supplied from the N+ semiconductor region 771-1. The FD 722B temporarily holds the electric charge supplied from the N+ semiconductor region 771-2.

The reset transistor 723A changes to a conductive state in response to a change of a reset drive signal RST supplied to a gate electrode into an active state to reset a potential of the FD 722A to a predetermined level (a reset level VDD). The reset transistor 723B changes to a conductive state in response to a change of a reset drive signal RST supplied to a gate electrode into an active state to reset a potential of the FD 722B to a predetermined level (a reset level VDD). Note that, when the reset transistors 723A and 723B change to an active state, the transfer transistors 721A and 721B also change to an active state at the same time.

Due to a source electrode being connected to the vertical signal line 29A via the selective transistor 725A, the amplifying transistor 724A constitutes a source follower circuit along with a load MOS of a constant-current source circuit portion 726A connected to one end of the vertical signal line 29A. Due to a source electrode being connected to the vertical signal line 29B via the selective transistor 725B, the amplifying transistor 724B constitutes a source follower circuit along with a load MOS of a constant-current source circuit portion 726B connected to one end of the vertical signal line 29B.

The selective transistor 725A is connected between the source electrode of the amplifying transistor 724A and the vertical signal line 29A. The selective transistor 725A changes to a conductive state in response to a change of a selection drive signal SEL supplied to a gate electrode into an active state to output a pixel signal output from the amplifying transistor 724A to the vertical signal line 29A.

The selective transistor 725B is connected between the source electrode of the amplifying transistor 724B and the vertical signal line 29B. The selective transistor 725B changes to a conductive state in response to a change of a selection drive signal SEL supplied to a gate electrode into an active state to output a pixel signal output from the amplifying transistor 724B to the vertical signal line 29B.

The transfer transistors 721A and 721B, the reset transistors 723A and 723B, the amplifying transistors 724A and 724B, and the selective transistors 725A and 725B of the pixel 10 are controlled by, for example, the vertical driving portion 22.

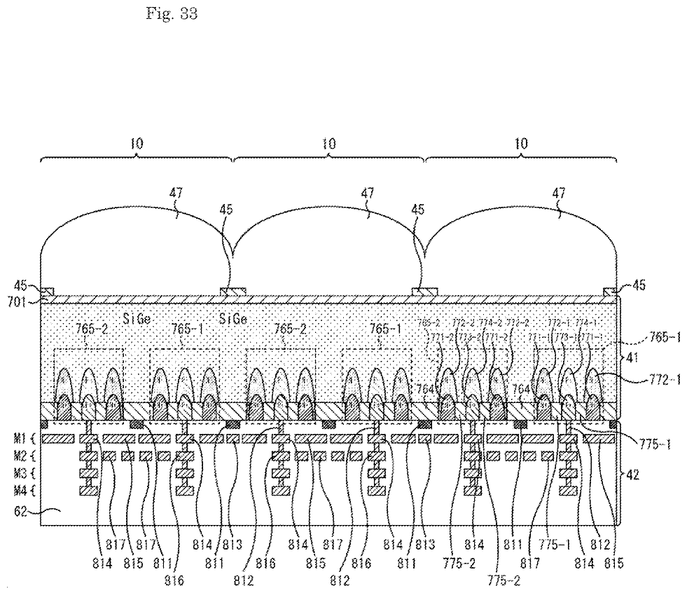

FIG. 33 is a sectional view in a case where the pixel 10 is a CAPD pixel.

In FIG. 33, portions corresponding to those in the other configuration examples described above are denoted by the same reference signs and descriptions of the portions will be appropriately omitted.

In the pixel 10 being a CAPD pixel, for example, an entirety of the semiconductor substrate 41 formed of a P-type is a photoelectric conversion region and is formed of the SiGe region or the Ge region described above. A surface of the semiconductor substrate 41 on which the on-chip lens 47 is formed is a light incident surface and a surface on an opposite side to the light incident surface is a circuit formation surface.

An oxide film 764 is formed in a central portion of the pixel 10 in a vicinity of a surface of the circuit formation surface of the semiconductor substrate 41, and a signal extracting portion 765-1 and a signal extracting portion 765-2 are respectively formed at both ends of the oxide film 764.

The signal extracting portion 765-1 includes an N+ semiconductor region 771-1 that is an N-type semiconductor region and an N− semiconductor region 772-1 with a lower concentration of donor impurities than the N+ semiconductor region 771-1, and a P+ semiconductor region 773-1 that is a P-type semiconductor region and a P− semiconductor region 774-1 with a lower concentration of acceptor impurities than the P+ semiconductor region 773-1. Examples of donor impurities include elements that belong to group 5 in the periodic table of the elements such as phosphorus (P) and arsenic (As) with respect to Si, and examples of acceptor impurities include elements that belong to group 3 in the periodic table of the elements such as boron (B) with respect to Si. An element that is a donor impurity will be referred to as a donor element and an element that is an acceptor impurity will be referred to as an acceptor element.

In the signal extracting portion 765-1, with the P+ semiconductor region 773-1 and the P− semiconductor region 774-1 as centers, the N+ semiconductor region 771-1 and the N− semiconductor region 772-1 are annularly formed so as to surround the P+ semiconductor region 773-1 and the P− semiconductor region 774-1. The P+ semiconductor region 773-1 and the N+ semiconductor region 771-1 are in contact with the multilayer wiring layer 42. The P− semiconductor region 774-1 is arranged above (on the side of the on-chip lens 47 of) the P+ semiconductor region 773-1 so as to cover the P+ semiconductor region 773-1, and the N− semiconductor region 772-1 is arranged above (on the side of the on-chip lens 47 of) the N+ semiconductor region 771-1 so as to cover the N+ semiconductor region 771-1. In other words, the P+ semiconductor region 773-1 and the N+ semiconductor region 771-1 are arranged on a side of the multilayer wiring layer 42 in the semiconductor substrate 41, and the N− semiconductor region 772-1 and the P− semiconductor region 774-1 are arranged on a side of the on-chip lens 47 in the semiconductor substrate 41. In addition, a separating portion 775-1 for separating the N+ semiconductor region 771-1 and the P+ semiconductor region 773-1 from each other is formed of an oxide film or the like between the regions.

In a similar manner, the signal extracting portion 765-2 includes an N+ semiconductor region 771-2 that is an N-type semiconductor region and an N− semiconductor region 772-2 with a lower concentration of donor impurities than the N+ semiconductor region 771-2, and a P+ semiconductor region 773-2 that is a P-type semiconductor region and a P− semiconductor region 774-2 with a lower concentration of acceptor impurities than the P+ semiconductor region 773-2.

In the signal extracting portion 765-2, with the P+ semiconductor region 773-2 and the P− semiconductor region 774-2 as centers, the N+ semiconductor region 771-2 and the N− semiconductor region 772-2 are annularly formed so as to surround the P+ semiconductor region 773-2 and the P− semiconductor region 774-2. The P+ semiconductor region 773-2 and the N+ semiconductor region 771-2 are in contact with the multilayer wiring layer 42. The P− semiconductor region 774-2 is arranged above (on the side of the on-chip lens 47 of) the P+ semiconductor region 773-2 so as to cover the P+ semiconductor region 773-2, and the N− semiconductor region 772-2 is arranged above (on the side of the on-chip lens 47 of) the N+ semiconductor region 771-2 so as to cover the N+ semiconductor region 771-2. In other words, the P+ semiconductor region 773-2 and the N+ semiconductor region 771-2 are arranged on a side of the multilayer wiring layer 42 in the semiconductor substrate 41, and the N− semiconductor region 772-2 and the P− semiconductor region 774-2 are arranged on a side of the on-chip lens 47 in the semiconductor substrate 41. In addition, a separating portion 775-2 for separating the N+ semiconductor region 771-2 and the P+ semiconductor region 773-2 from each other is also formed of an oxide film or the like between the regions.

The oxide film 764 is also formed between the N+ semiconductor region 771-1 of the signal extracting portion 765-1 of a predetermined pixel 10 and the N+ semiconductor region 771-2 of the signal extracting portion 765-2 of an adjacent pixel 10 which constitute boundary regions of adjacent pixels 10.

A P+ semiconductor region 701 in which a film having a positive fixed electric charge is laminated and which covers an entire light incident surface is formed at an interface on a side of the light incident surface of the semiconductor substrate 41.

Hereinafter, the signal extracting portion 765-1 and the signal extracting portion 765-2 will also be simply referred to as a signal extracting portion 765 when there is no particular need to distinguish between the signal extracting portion 765-1 and the signal extracting portion 765-2.

In addition, hereinafter, the N+ semiconductor region 771-1 and the N+ semiconductor region 771-2 will also be simply referred to as an N+ semiconductor region 771 when there is no particular need to distinguish between the N+ semiconductor region 771-1 and the N+ semiconductor region 771-2, and the N− semiconductor region 772-1 and the N− semiconductor region 772-2 will also be simply referred to as an N− semiconductor region 772 when there is no particular need to distinguish between the N− semiconductor region 772-1 and the N− semiconductor region 772-2.

Furthermore, hereinafter, the P+ semiconductor region 773-1 and the P+ semiconductor region 773-2 will also be simply referred to as a P+ semiconductor region 773 when there is no particular need to distinguish between the P+ semiconductor region 773-1 and the P+ semiconductor region 773-2, and the P− semiconductor region 774-1 and the P− semiconductor region 774-2 will also be simply referred to as a P− semiconductor region 774 when there is no particular need to distinguish between the P− semiconductor region 774-1 and the P− semiconductor region 774-2. In addition, the separating portion 775-1 and the separating portion 775-2 will also be simply referred to as a separating portion 775 when there is no particular need to distinguish between the separating portion 775-1 and the separating portion 775-2.

The N+ semiconductor region 771 provided on the semiconductor substrate 41 functions as an electric charge detecting portion for detecting an amount of light incident on the pixel 10 from the outside or, in other words, an amount of a signal electric charge generated according to photoelectric conversion by the semiconductor substrate 41. The electric charge detecting portion can also be regarded as including the N− semiconductor region 772 with a low concentration of donor impurities in addition to the N+ semiconductor region 771. In addition, the P+ semiconductor region 773 functions as a voltage applying portion for injecting a majority carrier current into the semiconductor substrate 41 or, in other words, directly applying a voltage to the semiconductor substrate 41 to generate an electric field inside the semiconductor substrate 41. The voltage applying portion can also be regarded as including the P− semiconductor region 774 with a low concentration of acceptor impurities in addition to the P+ semiconductor region 773.

For example, a diffusion film 811 that is regularly arranged at predetermined intervals is formed at an interface on a front surface side of the semiconductor substrate 41 which is a side on which the multilayer wiring layer 42 is formed. In addition, although not illustrated, an insulating film (gate insulating film) is formed between the diffusion film 811 and the interface of the semiconductor substrate 41.

For example, the diffusion film 811 is regularly arranged at predetermined intervals at an interface on the front surface side of the semiconductor substrate 41 which is a side on which the multilayer wiring layer 42 is formed and prevents light that passes from the semiconductor substrate 41 to the multilayer wiring layer 42 and light reflected by a reflecting member 815 (to be described later) from being diffused by the diffusion film 811 and penetrating to the outside (on the side of the on-chip lens 47) of the semiconductor substrate 41. A material of the diffusion film 811 may be any material containing a polycrystalline silicon such as polysilicon as a main component.

Note that the diffusion film 811 is formed so as to avoid positions of the N+ semiconductor region 771-1 and the P+ semiconductor region 773-1 so that the diffusion film 811 does not overlap with the positions of the N+ semiconductor region 771-1 and the P+ semiconductor region 773-1.

In FIG. 33, among a first metal film M1 to a fourth metal film M4 that constitute four layers of the multilayer wiring layer 42, the first metal film M1 that is closest to the semiconductor substrate 41 includes a power supply line 813 for supplying a power supply voltage, a voltage application wiring 814 for applying a predetermined voltage to the P+ semiconductor region 773-1 or 773-2, and the reflecting member 815 that is a member for reflecting incident light. The voltage application wiring 814 is connected to the P+ semiconductor region 773-1 or 773-2 via a contact electrode 812, applies a predetermined voltage MIX0 to the P+ semiconductor region 773-1, and applies a predetermined voltage MIX1 to the P+ semiconductor region 773-2.

In the first metal film M1 in FIG. 33, although the reflecting member 815 constitute wirings other than the power supply line 813 and the voltage application wiring 814, some reference signs have been omitted in order to prevent the drawing from becoming overcomplicated. The reflecting member 815 is dummy wiring that is provided in order to reflect incident light. The reflecting member 815 is arranged below the N+ semiconductor regions 771-1 and 771-2 that are electric charge detecting portions so as to overlap with the N+ semiconductor regions 771-1 and 771-2 in a plan view. In addition, in the first metal film M1, in order to transfer an electric charge accumulated in the N+ semiconductor region 771 to the FD 722, a contact electrode (not illustrated) that connects the N+ semiconductor region 771 and a transfer transistor 721 to each other is also formed.

While the reflecting member 815 is arranged on a same layer of the first metal film M1 in the present example, the reflecting member 815 is not necessarily limited to being arranged on a same layer.

In the second metal film M2 being a second layer from the side of the semiconductor substrate 41, for example, a voltage application wiring 816 connected to the voltage application wiring 814 of the first metal film M1, a control line 817 that transmits a transfer drive signal TRG, a reset drive signal RST, a selection drive signal SEL, an FD drive signal FDG, and the like, a ground line, and the like are formed. In addition, an FD 722 and the like are also formed in the second metal film M2.

In the third metal film M3 being a third layer from the side of the semiconductor substrate 41, for example, the vertical signal line 29, wiring for shielding, and the like are formed.

In the fourth metal film M4 being a fourth layer from the side of the semiconductor substrate 41, for example, a voltage supply line (not illustrated) for applying a predetermined voltage MIX0 or MIX1 is formed in the P+ semiconductor regions 773-1 and 773-2 that are voltage applying portions of a signal extracting portion 65.

An operation of the pixel 10 shown in FIG. 33 that is a CAPD pixel will be described.

The vertical driving portion 22 drives the pixel 10 and distributes signals in accordance with an electric charge obtained due to photoelectric conversion to the FD 722A and the FD 722B (FIG. 32).

The vertical driving portion 22 applies voltages to the two P+ semiconductor regions 773 via the contact electrode 812 or the like. For example, the vertical driving portion 22 applies a voltage of 1.5 V to the P+ semiconductor region 773-1 and applies a voltage of 0 V to the P+ semiconductor region 773-2.

Due to the application of voltages, an electric field is generated between the two P+ semiconductor regions 773 in the semiconductor substrate 41 and a current flows from the P+ semiconductor region 773-1 to the P+ semiconductor region 773-2. In this case, a hole in the semiconductor substrate 41 is to move in a direction of the P+ semiconductor region 773-2 and an electron is to move in a direction of the P+ semiconductor region 773-1.

Therefore, when infrared light (reflected light) from outside is incident to the semiconductor substrate 41 via the on-chip lens 47 in this state and the infrared light is photoelectrically converted in the semiconductor substrate 41 into a pair of an electron and a hole, the obtained electron is guided in a direction of the P+ semiconductor region 773-1 by the electric field between the P+ semiconductor regions 773 and moves into the N+ semiconductor region 771-1.

In this case, the electrons generated by photoelectric conversion is to be used as a signal electric charge for detecting a signal in accordance with an amount of infrared light incident to the pixel 10 or, in other words, an amount of received infrared light.

Accordingly, an electric charge in accordance with electrons having moved into the N+ semiconductor region 771-1 is to be accumulated in the N+ semiconductor region 771-1 and the electric charge is to be detected by the column processing portion 23 via the FD 722A, the amplifying transistor 724A, the vertical signal line 29A, and the like.

In other words, the accumulated electric charge of the N+ semiconductor region 771-1 is transmitted to the FD 722A being directly connected to the N+ semiconductor region 771-1, and a signal in accordance with the electric charge transmitted to the FD 722A is to be read by the column processing portion 23 via the amplifying transistor 724A and the vertical signal line 29A. In addition, processing such as AD conversion is performed by the column processing portion 23 with respect to the read signal and a pixel signal obtained as a result of the processing is supplied to the signal processing portion 26.

The pixel signal is a signal indicating an amount of electric charge in accordance with the electrons detected by the N+ semiconductor region 771-1 or, in other words, an amount of the electric charge accumulated in the FD 722A. In other words, the pixel signal can be described a signal indicating an amount of infrared light received by the pixel 10.

In this case, a pixel signal in accordance with electrons detected by the N+ semiconductor region 771-2 may be used for ranging when appropriate in a similar manner to the case of the N+ semiconductor region 771-1.

In addition, at a subsequent timing, a voltage is applied to two P+ semiconductor regions 73 by the vertical driving portion 22 via a contact or the like so that an electric field in an opposite direction to an electric field generated until now in the semiconductor substrate 41 is generated. Specifically, for example, a voltage of 1.5 V is applied to the P+ semiconductor region 773-2 and a voltage of 0 V is applied to the P+ semiconductor region 773-1.

Accordingly, an electric field is generated between the two P+ semiconductor regions 773 in the semiconductor substrate 41 and a current flows from the P+ semiconductor region 773-2 to the P+ semiconductor region 773-1.

When infrared light (reflected light) from outside is incident to the semiconductor substrate 41 via the on-chip lens 47 in such a state, the infrared light is photoelectrically converted inside the semiconductor substrate 41 into a pair of an electron and a hole, the obtained electron is guided in a direction of the P+ semiconductor region 773-2 by the electric field between the two P+ semiconductor regions 773 and moves into the N+ semiconductor region 771-2.

Accordingly, an electric charge in accordance with the electron having moved into the N+ semiconductor region 771-2 is to be accumulated in the N+ semiconductor region 771-2 and the electric charge is to be detected by the column processing portion 23 via the FD 722B, the amplifying transistor 724B, the vertical signal line 29B, and the like.

In other words, an accumulated electric charge of the N+ semiconductor region 771-2 is transferred to the FD 722B that is directly connected to the N+ semiconductor region 771-2, and a signal in accordance with the electric charge transferred to the FD 722B is read by the column processing portion 23 via the amplifying transistor 724B and the vertical signal line 29B. In addition, processing such as AD conversion is performed by the column processing portion 23 with respect to the read signal and a pixel signal obtained as a result of the processing is supplied to the signal processing portion 26.

In this case, a pixel signal in accordance with electrons detected by the N+ semiconductor region 771-1 may be used for ranging when appropriate in a similar manner to the case of the N+ semiconductor region 771-2.

In this manner, when pixel signals are obtained by photoelectric conversions performed during mutually different periods in the same pixel 10, the signal processing portion 26 can calculate a distance to an object based on the pixel signals.

Even in the pixel 10 as a CAPD pixel configured as described above, by forming the semiconductor substrate 41 of a SiGe region or a Ge region, quantum efficiency of near-infrared light can be enhanced and sensor sensitivity can be improved.

### <21. Configuration Example of Ranging Module>

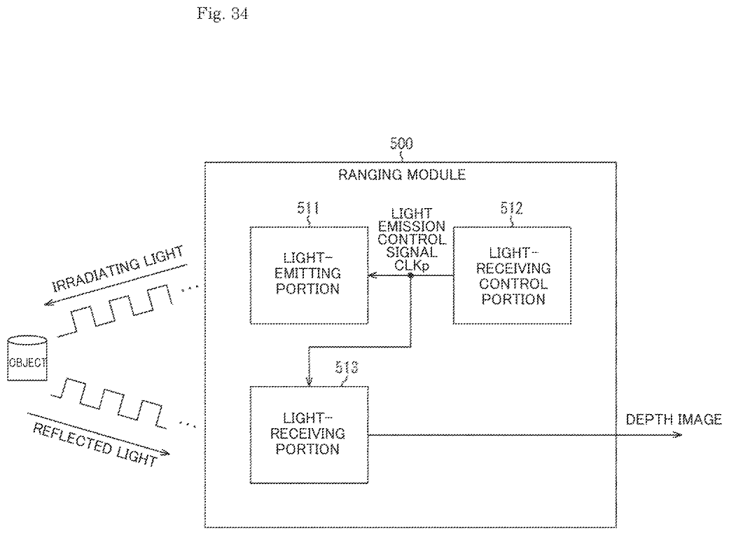

FIG. 34 is a block diagram showing a configuration example of a ranging module that outputs ranging information using the light-receiving element 1 described above.

A ranging module 500 includes a light-emitting portion 511, a light emission control portion 512, and a light-receiving portion 513.

The light-emitting portion 511 includes a light source that emits light having a predetermined wavelength, and irradiates an object with irradiating light of which a brightness varies periodically. For example, the light-emitting portion 511 includes a light-emitting diode that emits infrared light with a wavelength of 780 nm or more as a light source, and generates irradiating light in synchronization with a light emission control signal CLKp of a rectangular wave supplied from the light emission control portion 512.

Note that the light emission control signal CLKp is not limited to a rectangular wave as long as it is a period signal. For example, the light emission control signal CLKp may be a sine wave.

The light emission control portion 512 supplies the light emission control signal CLKp to the light-emitting portion 511 and the light-receiving portion 513 and controls an irradiation timing of irradiating light. The frequency of the light emission control signal CLKp is, for example, 20 megahertz (MHz). Note that the frequency of the light emission control signal CLKp is not limited to 20 megahertz and may be 5 megahertz, 100 megahertz, or the like.

The light-receiving portion 513 receives reflected light having been reflected by an object, calculates distance information for each pixel in accordance with a result of light reception, and generates and outputs a depth image in which a depth value corresponding to a distance to the object (subject) is stored as a pixel value.

In the light-receiving portion 513, the light-receiving element 1 having a pixel structure of the indirect ToF system (a gate system or a CAPD system) described above or a light-receiving element 1 having a pixel structure of a SPDAD pixel is used. For example, the light-receiving element 1 as the light-receiving portion 513 calculates distance information for each pixel from a pixel signal in accordance with an electric charge distributed to the floating diffusion region FD1 or FD2 of each pixel 10 of the pixel array portion 21 based on the light emission control signal CLKp.

As described above, the light-receiving element 1 having the pixel structure of the indirect ToF system or the pixel structure of the direct ToF system described above can be incorporated as the light-receiving portion 513 of the ranging module 500 that obtains and outputs information on a distance to a subject. Accordingly, sensor sensitivity can be improved and ranging characteristics as the ranging module 500 can be improved.

### <22. Configuration Example of Electronic Device>

Note that, as described above, the light-receiving element 1 can be applied to a ranging module, and can also be applied to various electronic devices such as, for example, imaging apparatuses such as digital still cameras and digital video cameras equipped with a ranging function, and smartphones equipped with a ranging function.

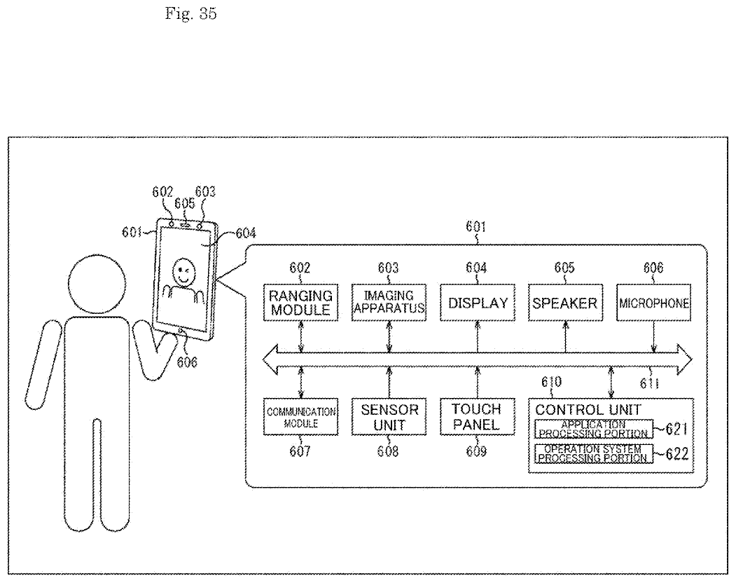

FIG. 35 is a block diagram showing a configuration example of a smartphone as an electronic device to which the present technique is applied.

As shown in FIG. 35, a smartphone 601 is configured such that a ranging module 602, an imaging apparatus 603, a display 604, a speaker 605, a microphone 606, a communication module 607, a sensor unit 608, a touch panel 609, and a control unit 610 are connected to each other via a bus 611. Furthermore, the control unit 610 has functions as an application processing portion 621 and an operation system processing portion 622 by causing a CPU to execute a program.

The ranging module 500 shown in FIG. 34 is applied to the ranging module 602. For example, the ranging module 602 is arranged on a front surface of the smartphone 601 and, by performing ranging with a user of the smartphone 601 as an object, the ranging module 602 can output a depth value of a surface shape of the face, a hand, a finger, or the like of the user as a ranging result.

The imaging apparatus 603 is arranged on the front surface of the smartphone 601 and, by imaging the user of the smartphone 601 as a subject, acquires an image capturing the user. Note that, although not illustrated, a configuration in which the imaging apparatus 603 is also arranged on the back surface of the smartphone 601 may be adopted.

The display 604 displays an operation screen for performing processing by the application processing portion 621 and the operation system processing portion 622, an image captured by the imaging apparatus 603, and the like. The speaker 605 and the microphone 606 perform, for example, output of sound from a counterpart and collection of user's sound when making a call using the smartphone 601.

The communication module 607 performs network communication through a communication network such as the Internet, a public telephone network, a wide area communication network for wireless mobile bodies such as a so-called 4G line and 5G line, a WAN (Wide Area Network), and LAN (Local Area Network), short-range wireless communication such as Bluetooth (registered trademark) and NFC (Near Field Communication), and the like. The sensor unit 608 senses speed, acceleration, proximity, and the like, and the touch panel 609 acquires a user's touch operation on the operation screen displayed on the display 604.

The application processing portion 621 performs processing for providing various services through the smartphone 601. For example, the application processing portion 621 can create a face by computer graphics that virtually reproduces the user's facial expression based on a depth value supplied from the ranging module 602, and can perform processing for displaying the face on the display 604. In addition, the application processing portion 621 can perform processing of creating, for example, three-dimensional shape data of an arbitrary three-dimensional object based on a depth value supplied from the ranging module 602.

The operation system processing portion 622 performs processing for realizing basic functions and operations of the smartphone 601. For example, the operation system processing portion 622 can perform processing for authenticating a user's face based on a depth value supplied from the ranging module 602, and unlocking the smartphone 601. In addition, the operation system processing portion 622 can perform, for example, processing for recognizing a user's gesture based on a depth value supplied from the ranging module 602, and can perform processing for inputting various operations according to the gesture.

In the smartphone 601 configured in this manner, applying the ranging module 500 described above as the ranging module 602 enables performing, for example, processing for measuring and displaying a distance to a predetermined object, creating and displaying three-dimensional shape data of a predetermined object, and the like.

### <23. Example of Application to Mobile Body>

The technique according to the present disclosure (the present technique) can be applied to various products. For example, the technique according to the present disclosure may be realized as an apparatus to be equipped in any type of mobile body such as an automobile, an electric vehicle, a hybrid electric vehicle, a motorcycle, a bicycle, a personal mobility device, an airplane, a drone, a ship, and a robot.

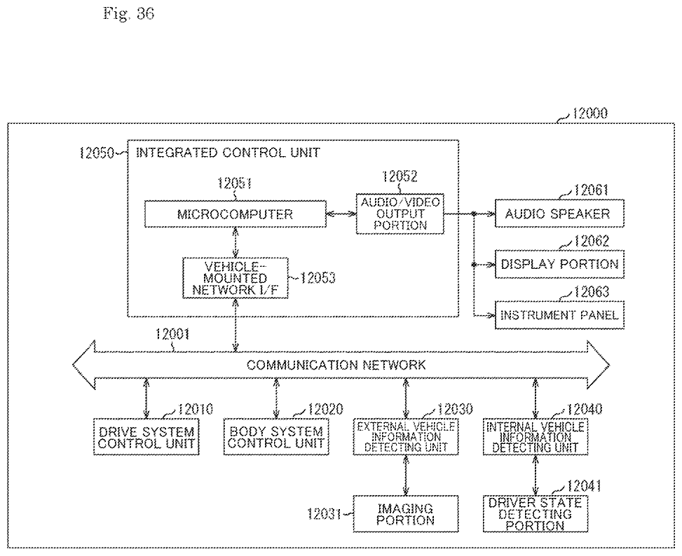

FIG. 36 is a block diagram showing a schematic configuration example of a vehicle control system that is an example of a mobile body control system to which the technique according to the present disclosure can be applied.

A vehicle control system 12000 includes a plurality of electronic control units connected via a communication network 12001. In the example shown in FIG. 36, the vehicle control system 12000 includes a drive system control unit 12010, a body system control unit 12020, an external vehicle information detecting unit 12030, an internal vehicle information detecting unit 12040, and an integrated control unit 12050. In addition, as functional components of the integrated control unit 12050, a microcomputer 12051, an audio/image output portion 12052, and a vehicle-mounted network I/F (interface) 12053 are shown in the drawing.

The drive system control unit 12010 controls an operation of an apparatus related to a drive system of a vehicle according to various programs. For example, the drive system control unit 12010 functions as a driving force generation apparatus for generating a driving force of a vehicle such as an internal combustion engine or a driving motor, a driving force transmission mechanism for transmitting a driving force to wheels, a steering mechanism for adjusting a turning angle of a vehicle, and a control apparatus such as a braking apparatus that generates a braking force of a vehicle.

The body system control unit 12020 controls operations of various apparatuses mounted in the vehicle body according to various programs. For example, the body system control unit 12020 functions as a control apparatus of a keyless entry system, a smart key system, a power window apparatus, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock apparatus, a power window apparatus, and a lamp of the vehicle.

The external vehicle information detecting unit 12030 detects information on the outside of the vehicle mounted with the vehicle control system 12000. For example, an imaging portion 12031 is connected to the external vehicle information detecting unit 12030. The external vehicle information detecting unit 12030 causes the imaging portion 12031 to capture an image of the outside of the vehicle and receives the captured image. The external vehicle information detecting unit 12030 may perform object detection processing or distance detection processing with respect to people, cars, obstacles, signs, and letters on the road based on the received image.

The imaging portion 12031 is an optical sensor that receives light and outputs an electrical signal according to the amount of the received light. The imaging portion 12031 can also output the electrical signal as an image or as ranging information. In addition, the light received by the imaging portion 12031 may be visible light or invisible light such as infrared light.

The internal vehicle information detecting unit 12040 detects information on the inside of the vehicle. For example, a driver state detecting portion 12041 that detects a driver's state is connected to the internal vehicle information detecting unit 12040. The driver state detecting portion 12041 includes, for example, a camera that captures an image of a driver, and the internal vehicle information detecting unit 12040 may calculate a degree of fatigue or concentration of the driver or may determine whether or not the driver is dozing based on detected information input from the driver state detecting portion 12041.

The microcomputer 12051 can calculate a control target value for the driving force generation apparatus, the steering mechanism, or the braking apparatus based on information on the inside or the outside of the vehicle acquired by the external vehicle information detecting unit 12030 or the internal vehicle information detecting unit 12040 and output a control command to the drive system control unit 12010. For example, the microcomputer 12051 can perform cooperative control for the purpose of implementing functions of an ADAS (advanced driver assistance system) including vehicle collision avoidance or shock mitigation, car-following driving based on an inter-vehicle distance, constant-speed driving, a vehicle collision warning, and a vehicle lane deviation warning.

Furthermore, the microcomputer 12051 can perform cooperative control for the purpose of automated driving or the like in which autonomous travel is performed without depending on operations of the driver by controlling the driving force generation apparatus, the steering mechanism, the braking apparatus, or the like based on information about the surroundings of the vehicle as acquired by the external vehicle information detecting unit 12030 or the internal vehicle information detecting unit 12040.

In addition, the microcomputer 12051 can output a control command to the body system control unit 12020 based on the information on the outside of the vehicle as acquired by the external vehicle information detecting unit 12030. For example, the microcomputer 12051 can perform cooperative control for the purpose of preventing glare by controlling the headlamp according to the position of a preceding vehicle or an oncoming vehicle detected by the external vehicle information detecting unit 12030 to, for example, switch from a high beam to a low beam.

The audio/image output portion 12052 transmits an output signal of at least one of sound and an image to an output apparatus capable of visually or audibly notifying a passenger or the outside of the vehicle of information. In the example shown in FIG. 36, an audio speaker 12061, a display portion 12062, and an instrument panel 12063 are illustrated as examples of the output apparatus. The display portion 12062 may include at least one of an on-board display and a head-up display, for example.

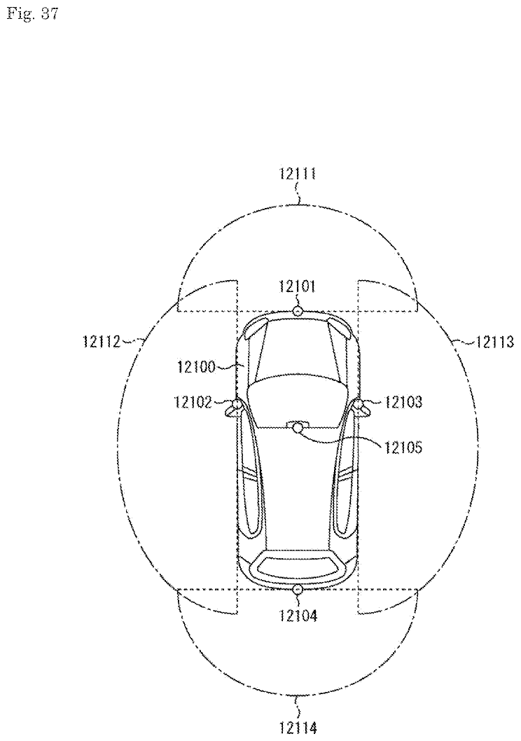

FIG. 37 is a diagram showing an example of an installation position of the imaging portion 12031.

In FIG. 37, a vehicle 12100 includes imaging portions 12101, 12102, 12103, 12104, and 12105 as the imaging portion 12031.

The imaging portions 12101, 12102, 12103, 12104, and 12105 are provided at positions such as a front nose, side-view mirrors, a rear bumper, a back door, and an upper portion of a windshield in a vehicle interior of the vehicle 12100. The imaging portion 12101 provided on the front nose and the imaging portion 12105 provided in the upper portion of the windshield in the vehicle interior mainly acquire images of the front of the vehicle 12100. The imaging portions 12102 and 12103 provided on the side-view mirrors mainly acquire images of a lateral side of the vehicle 12100. The imaging portion 12104 provided on the rear bumper or the back door mainly acquires images of the rear of the vehicle 12100. Front view images acquired by the imaging portions 12101 and 12105 are mainly used for detection of preceding vehicles, pedestrians, obstacles, traffic lights, traffic signs, lanes, and the like.

FIG. 37 shows an example of imaging ranges of the imaging portions 12101 to 12104. An imaging range 12111 indicates an imaging range of the imaging portion 12101 provided at the front nose, imaging ranges 12112 and 12113 respectively indicate the imaging ranges of the imaging portions 12102 and 12103 provided at the side-view mirrors, and an imaging range 12114 indicates the imaging range of the imaging portion 12104 provided at the rear bumper or the back door. For example, by superimposing image data captured by the imaging portions 12101 to 12104, it is possible to obtain a bird's-eye view image of the vehicle 12100 as viewed from above.

At least one of the imaging portions 12101 to 12104 may have a function for acquiring distance information. For example, at least one of the imaging portions 12101 to 12104 may be a stereo camera constituted by a plurality of imaging elements or may be an imaging element that has pixels for phase difference detection.

For example, the microcomputer 12051 can extract, particularly, a closest three-dimensional object on a path through which the vehicle 12100 is traveling, which is a three-dimensional object traveling at a predetermined speed (for example, 0 km/h or higher) in the substantially same direction as the vehicle 12100, as a preceding vehicle by acquiring a distance to each three-dimensional object in the imaging ranges 12111 to 12114 and temporal change in a distance (a relative speed with respect to the vehicle 12100) to the three-dimensional object based on distance information obtained from the imaging portions 12101 to 12104. Furthermore, the microcomputer 12051 can set an inter-vehicle distance to be secured in advance in front of a preceding vehicle and can perform automated brake control (also including car-following stop control) or automated acceleration control (also including car-following start control). In this manner, cooperative control for the purpose of automated driving in which the vehicle autonomously travels without the need for driver's operations can be performed.

For example, the microcomputer 12051 can classify and extract three-dimensional data regarding three-dimensional objects into two-wheeled vehicles, normal vehicles, large vehicles, pedestrians, and other three-dimensional objects such as utility poles based on distance information obtained from the imaging portions 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating a degree of risk of collision with each obstacle, and when the collision risk is equal to or higher than a set value and there is a possibility of collision, driving support for collision avoidance can be performed by outputting an alarm to the driver through the audio speaker 12061 or the display portion 12062 or performing forced deceleration or avoidance steering through the drive system control unit 12010.

At least one of the imaging portions 12101 to 12104 may be an infrared camera that detects infrared light. For example, the microcomputer 12051 can recognize a pedestrian by determining whether there is a pedestrian in a captured image of the imaging portions 12101 to 12104. Such pedestrian recognition is performed by, for example, a procedure in which feature points in captured images of the imaging portions 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging portions 12101 to 12104 and the pedestrian is recognized, the audio/image output portion 12052 controls the display portion 12062 so that a square contour line for emphasis is superimposed and displayed with the recognized pedestrian. In addition, the audio/image output portion 12052 may control the display portion 12062 so that an icon indicating a pedestrian or the like is displayed at a desired position.

An example of the vehicle control system to which the technique according to the present disclosure can be applied has been described above. The technique according to the present disclosure can be applied to the external vehicle information detecting unit 12030 and the imaging portion 12031 among the above-described components. Specifically, the light-receiving element 1 or the ranging module 500 can be applied to a distance detection processing block of the external vehicle information detecting unit 12030 and the imaging portion 12031. By applying the technique according to the present disclosure to the external vehicle information detecting unit 12030 and the imaging portion 12031, it is possible to measure a distance to an object such as a person, a vehicle, an obstacle, a sign, or a character on a road surface with high accuracy and to reduce a driver's fatigue of a driver and improve the safety level of a driver and a vehicle by using obtained distance information.

The embodiments of the present technique are not limited to the aforementioned embodiments and various modifications can be made without departing from the gist of the present technique.

Furthermore, while an example in which electrons are used as signal carriers has been described in the light-receiving element 1 described above, alternatively, holes generated by photoelectric conversion may be used as signal carriers.

For example, a combination of all of or a part of the respective embodiments can be adopted in the light-receiving element 1 described above.

The advantageous effects described in the present specification are merely exemplary and are not limited, and advantageous effects other than those described in the present specification may be achieved.

The present technique can be configured as follows.

(1)
A light-receiving element, including:
a pixel array region where pixels in which at least a photoelectric conversion region is formed of a SiGe region or a Ge region are arrayed in a matrix pattern; and
an AD converting portion provided in pixel units of one or more pixels.
(2)
The light-receiving element according to (1) above, wherein
an entirety of the pixel array region is formed of the SiGe region or the Ge region.
(3)
The light-receiving element according to (1) or (2) above, wherein
the pixel includes at least a photodiode as the photoelectric conversion region, a transfer transistor configured to transfer an electric charge generated in the photodiode, and an electric charge holding portion configured to temporarily hold the electric charge, and
the light-receiving element includes a capacitative element connected to the electric charge holding portion.
(4)
The light-receiving element according to (3) above, wherein
the capacitative element is a MIM capacitative element formed in a wiring layer.
(5)
The light-receiving element according to (3) above, wherein the capacitative element is a MOM capacitative element formed in a wiring layer.
(6)
The light-receiving element according to (3) above, wherein
the capacitative element is a Poly-Poly capacitative element formed in a wiring layer.
(7)
The light-receiving element according to any one of (1) to (6) above, wherein
the light-receiving element is constructed by laminating a first semiconductor substrate on which the pixel array region is formed and a second semiconductor substrate on which a logic circuit region including a control circuit of each pixel is formed.
(8)
The light-receiving element according to any one of (1) to (7) above, wherein
the AD converting portion is provided in units of n×n-number of pixels (where n is an integer equal to or larger than 2).
(9)
The light-receiving element according to any one of (1) to (8) above, wherein
the light-receiving element is an indirect ToF sensor adopting a gate system.
(10)
The light-receiving element according to any one of (1) to (8) above, wherein
the light-receiving element is an indirect ToF sensor adopting a CAPD system.
(11)
The light-receiving element according to any one of (1) to (8) above, wherein
the light-receiving element is a direct ToF sensor including a SPAD in the pixel.
(12)
The light-receiving element according to any one of (1) to (8) above, wherein
the light-receiving element is an IR imaging sensor in which all pixels are pixels configured to receive infrared light.
(13)
The light-receiving element according to any one of (1) to (8) above, wherein
the light-receiving element is an RGBIR imaging sensor including a pixel configured to receive infrared light and a pixel configured to receive RGB light.
(14)
A method of manufacturing a light-receiving element including a pixel array region where pixels are arrayed in a matrix pattern and an AD converting portion provided in pixel units of one or more pixels, the method including:
forming at least the photoelectric conversion region of each pixel of a SiGe region or a Ge region.
(15)
The method of manufacturing a light-receiving element according to (14) above, wherein
an entirety of the pixel array region is formed of the SiGe region or the Ge region.
(16)
The method of manufacturing a light-receiving element according to (14) or (15) above, including
forming a silicon film by epitaxial growth on a pixel transistor formation surface of a semiconductor substrate on which the photoelectric conversion region has been formed and
forming an oxide film by heat-treating the silicon film.
(17)
The method of manufacturing a light-receiving element according to (16) above, wherein
the oxide film is a gate oxide film of a pixel transistor.
(18)
An electronic device, including:
a light-receiving element, including:
a pixel array region where pixels in which at least a photoelectric conversion region is formed of a SiGe region or a Ge region are arrayed in a matrix pattern; and
an AD converting portion provided in pixel units of one or more pixels.

### REFERENCE SIGNS LIST

1 Light-receiving element
10 Pixel
PD Photodiode
TRG Transfer transistor
21 Pixel array portion
41 Semiconductor substrate (first substrate)
42 Multilayer wiring layer
50 P-type semiconductor region
52 N-type semiconductor region
111 Pixel array region
141 Semiconductor substrate (second substrate)
201 Pixel circuit
202 ADC (AD convertor)
351 Oxide film
371 MIM capacitative element
381 First color filter layer
382 Second color filter layer
441 N well region
442 P-type diffusion layer
500 Ranging module
511 Light-emitting portion
512 Light emission control portion
513 Light-receiving portion
601 Smartphone
602 Ranging module

What is claimed is:

1. A light-receiving element, comprising:
a pixel array region where pixels in which at least a photoelectric conversion region is formed of a SiGe region or a Ge region are arrayed in a matrix pattern; and
an AD converting portion provided in pixel units of one or more pixels.

2. The light-receiving element according to claim 1, wherein
an entirety of the pixel array region is formed of the SiGe region or the Ge region.

3. The light-receiving element according to claim 1, wherein
the pixel includes at least a photodiode as the photoelectric conversion region, a transfer transistor configured to transfer an electric charge generated in the photodiode, and an electric charge holding portion configured to temporarily hold the electric charge, and
the light-receiving element comprises a capacitative element connected to the electric charge holding portion.

4. The light-receiving element according to claim 3, wherein
the capacitative element is a MIM capacitative element.

5. The light-receiving element according to claim 3, wherein
the capacitative element is a MOM capacitative element.

6. The light-receiving element according to claim 3, wherein
the capacitative element is a Poly-Poly capacitative element.

7. The light-receiving element according to claim 1, wherein
the light-receiving element is constructed by laminating a first semiconductor substrate on which the pixel array region is formed and a second semiconductor substrate on which a logic circuit region including a control circuit of each pixel is formed.

8. The light-receiving element according to claim 1, wherein
the AD converting portion is provided in units of n×n-number of pixels (where n is an integer equal to or larger than 2).

9. The light-receiving element according to claim 1, wherein
the light-receiving element is an indirect ToF sensor adopting a gate system.

10. The light-receiving element according to claim 1, wherein
the light-receiving element is an indirect ToF sensor adopting a CAPD system.

11. The light-receiving element according to claim 1, wherein
the light-receiving element is a direct ToF sensor including a SPAD in the pixel.

12. The light-receiving element according to claim 1, wherein
the light-receiving element is an IR imaging sensor in which all pixels are pixels configured to receive infrared light.

13. The light-receiving element according to claim 1, wherein
the light-receiving element is an RGBIR imaging sensor including a pixel configured to receive infrared light and a pixel configured to receive RGB light.

14. A method of manufacturing a light-receiving element including a pixel array region where pixels are arrayed in a matrix pattern and an AD converting portion provided in pixel units of one or more pixels, the method comprising:
forming at least a photoelectric conversion region of each pixel of a SiGe region or a Ge region.

15. The method of manufacturing a light-receiving element according to claim 14, wherein
an entirety of the pixel array region is formed of the SiGe region or the Ge region.

16. The method of manufacturing a light-receiving element according to claim 14, comprising
forming a silicon film by epitaxial growth on a pixel transistor formation surface of a semiconductor substrate on which the photoelectric conversion region has been formed and forming an oxide film by heat-treating the silicon film.

17. The method of manufacturing a light-receiving element according to claim 16, wherein
the oxide film is a gate oxide film of a pixel transistor.

18. An electronic device, comprising
a light-receiving element, including:
a pixel array region where pixels in which at least a photoelectric conversion region is formed of a SiGe region or a Ge region are arrayed in a matrix pattern; and
an AD converting portion provided in pixel units of one or more pixels.
